(19) United States
(12) Patent Application Publication
(10) Pub. No.: US 2025/0374504 A1
(43) Pub. Date: Dec. 4, 2025

(54) SEMICONDUCTOR STRUCTURE AND FORMING METHOD THEREOF

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/733,536

(22) Filed: Jun. 4, 2024

(51) Int. Cl. H10B 10/00

(52) U.S. Cl. CPC H10B 10/125

(57) ABSTRACT

A method of forming a semiconductor structure includes a number of operations. A first static random access memory (SRAM) cell is formed over a semiconductive substrate. A second SRAM cell is formed over the semiconductive substrate and adjacent to the first SRAM cell. A first source/drain contact is formed across the first and second SRAM cells, wherein the first source/drain contact is electrically coupled to a source/drain region of a first pass-gate transistor in the first SRAM cell and a source/drain region of a second pass-gate transistor in the second SRAM cell. A first source/drain contact via is formed over the first source/drain contact.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a static random access memory (SRAM) cell, in accordance with some embodiments of the disclosure.

FIG. 1B illustrates a simplified diagram of the memory cell of FIG. 1A, in accordance with some embodiments of the present disclosure.

FIG. 2A illustrates a layout of a semiconductor structure, in accordance with some embodiments of the present disclosure.

FIG. 2B illustrates the column of the layout of the semiconductor structure as shown in FIG. 2A, in accordance with some embodiments of the present disclosure.

FIG. 2C illustrates an example top view of a contact via of FIG. 2B, in accordance with some embodiments of the present disclosure.

FIGS. 3A through 3K illustrate cross-sectional views obtained from reference cross-sections C1-C1′, C2-C2′, C3-C3′, C4-C4′, C5-C5′, C6-C6′ and C7-C7 in FIG. 2B.

FIG. 4A illustrates a cell array layout diagram of the semiconductor structure in accordance with some embodiments of the present disclosure.

FIG. 4B illustrates a top view of the metal line and the metal portion overlapping the underlying interconnect via according to one or more embodiments of the present disclosure.

FIG. 5 illustrates a cell array layout diagram of the semiconductor structure in accordance with some embodiments of the present disclosure.

FIG. 6 illustrates a simplified diagram of the column in the semiconductor structure, in accordance with some embodiments of the present disclosure.

FIG. 7 illustrates a layout of a semiconductor structure 100, in accordance with some embodiments, in accordance with some embodiments of the present disclosure.

FIG. 8A illustrates a layout of a semiconductor structure, in accordance with some embodiments of the present disclosure.

FIG. 8B illustrates a column of the layout of FIG. 8A, in accordance with some embodiments of the present disclosure.

FIG. 9 illustrates a cross-sectional view obtained from a reference cross-sections C8-C8′ in FIG. 8B.

FIG. 10 illustrate a layout of a semiconductor structure, in accordance with some embodiments.

FIG. 11 illustrate a cell array layout diagram of a semiconductor structure, in accordance with some embodiments.

FIG. 12 illustrates a cell array layout diagram of a semiconductor structure, in accordance with some embodiments.

FIG. 13 illustrates a schematic view of a semiconductor structure in accordance with some embodiments of the present disclosure.

FIGS. 14 through 19C illustrate schematic views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, static random access memory (SRAM) bit-lines may dispose in lowest level metallization layer (M1) for bit-line capacitance reduction. However, when metal thickness and line width are continuous shrunk, the lowest level metal may push the metal pitch to limitation for logic circuit routing density improvement, which in turn leads to increased resistance in both SRAM bit-line and Vss conductors (IR drop concern), and therefore impact the cell speed and V_min performance.

Therefore, the present disclosure in various embodiments provides a SRAM array may include plurality of grouped memory cells in word-line routing direction, and each grouped cell may include two adjacent cells that placed in word-line routing direction and shared one bit-line pair. The merged two SRAM cells with one bit-line pair allows for a wider width for the bit line, which in turn allows for a decrease in resistance and an increase in array size (i.e., more columns and rows) for capacitance reduction. In some embodiments, the bit-line node connection may include an elongated contact layer electrically connected to the source/drain regions of both pass-gate transistor devices of the two adjacent SRAM cells, and an elongated via-0 layer landed upon said elongated contact, and first metal layer (M1) partially connected to the elongated via-0 layer, and have via-1, M2 layer and via-2 stacked connection to bit-line conductor (M3 layer). The M3 bit-line having a line shape with extra metal extension portion overlapping Via-2 portion can provide enough connection margin between M3 and Via-2 to achieve lower connection resistance and have wider space between bit line and Vss for reduction of bit-line capacitance. The continuous pull-up active regions in the SRAM cells with isolation structure can solve both pull-up active region line end shrink control problem and pull-up layout-induced effects (LOD) effect.

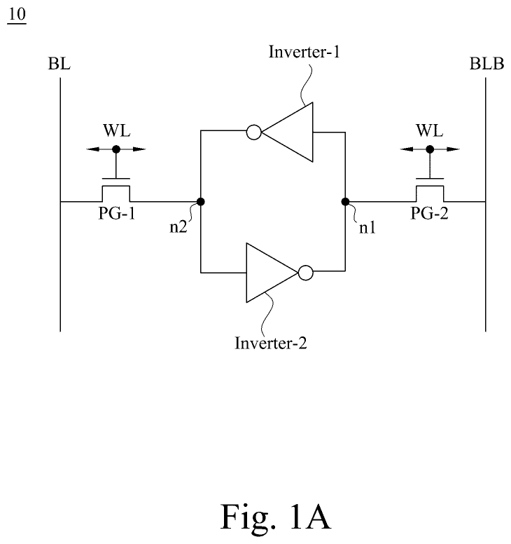

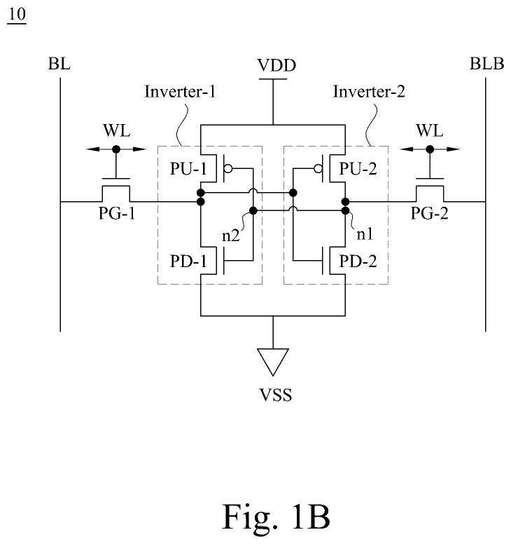

Reference is made to FIGS. 1A and 1B. FIGS. 1A and 1B illustrates a circuit diagram of a static random access memory (SRAM) cell 10 in accordance with some embodiments of the present disclosure. FIG. 1A illustrates a SRAM cell 10, in accordance with some embodiments of the disclosure. FIG. 1B illustrates a simplified diagram of the memory cell 10 of FIG. 1A, in accordance with some embodiments of the present disclosure. In one or more embodiments of the present disclosure, the memory cell 10 as illustrated in FIGS. 1A and 1B may be a single-port SRAM cell.

As illustrated in FIG. 1A, the memory cell 10 may include a pair of cross-coupled inverters Inverter-1 and Inverter-2 and two pass-gate transistors PG-1 and PG-2. The inventers Inventer-1 and Inventer-2 are cross-coupled between the nodes n1 and n2, and form a latch circuit. In some embodiments, one of the nodes n1 and n2 is used as an output terminal of the latch circuit and the other node is used as in input terminal of the latch circuit. The pass-gate transistor PG-1 is coupled between a bit line BL and the node n2, and the pass-gate transistor PG-2 is coupled between a complementary bit line BLB and the node n1, wherein the complementary bit line BLB is complementary to the bit line BL. The gates of the pass-gate transistors PG-1 and PG-2 are coupled to the same word line WL. Furthermore, in some embodiments, the pass-gate transistors PG-1 and PG-2 are NMOS transistor. In some embodiments, the memory cell 10 may include two isolation transistors, wherein the sources of the isolation transistors are floating and the gates and the drains of one of the isolation transistors are coupled to one of the nodes n1 and n2. In some embodiments, the isolation transistors may be PMOS transistors.

FIG. 1B shows a simplified diagram of the memory cell of FIG. 1A, in accordance with some embodiments of the present disclosure. The inverter Inverter-1 includes a pull-up transistor PU-1 and a pull-down transistor PD-1. The pull-up transistor PU-1 may be a PMOS transistor, and the pull-down transistor PD-1 may be an NMOS transistor. The drain of the pull-up transistor PU-1 and the drain of the pull-down transistor PD-1 are coupled to the node n2 connecting the pass-gate transistor PG1. The gates of the pull-up transistor PU-1 and the pull-down transistor PD1 are couple to the node n1 connecting the pass-gate transistor PG-2. Furthermore, the source of the pull-up transistor PU-1 is coupled to the power supply VDD, and the source of the pull-down transistor PD-1 is coupled to a ground VSS.

Similarly, the inverter Inverter-2 includes a pull-up transistor PU-2 and a pull-down transistor PD-2. The pull-up transistor PU-2 may be a PMOS transistor, and the pull-down transistor PD-2 may be a NMOS transistor. The drains of the pull-up transistor PU-2 and the pull-down transistor PD-2 are coupled to the node n1 connecting the pass-gate transistor PG-2. The gates of the pull-up transistor PU-2 and the pull-down transistor PD-2 are coupled to the node n1 connecting the pass-gate transistor PG-1. Furthermore, the source of the pull-up transistor PU-2 is coupled to the power supply VDD, and the source of the pull-down transistor PD-2 is coupled to the ground VSS.

In some embodiments that the memory cell 10 includes two isolation transistors, the drain and the gate of one of the isolation transistors are both coupled to the node n2 and the drain and the gate of another one of the isolation transistors are both coupled to the node n1. The sources of the isolation transistors are depicted as flowing. In some embodiments, the sources of the isolation transistors may be coupled to respective transistors in adjacent memory cells.

In some embodiments, the pass-gate transistors PG-1 and PG-2, the pull-up transistors PU-1 and PU-2, the pull-down transistors PD-1 and PD-2, and the isolation transistors of the memory cells 10 may be gate all around (GAA) FETs.

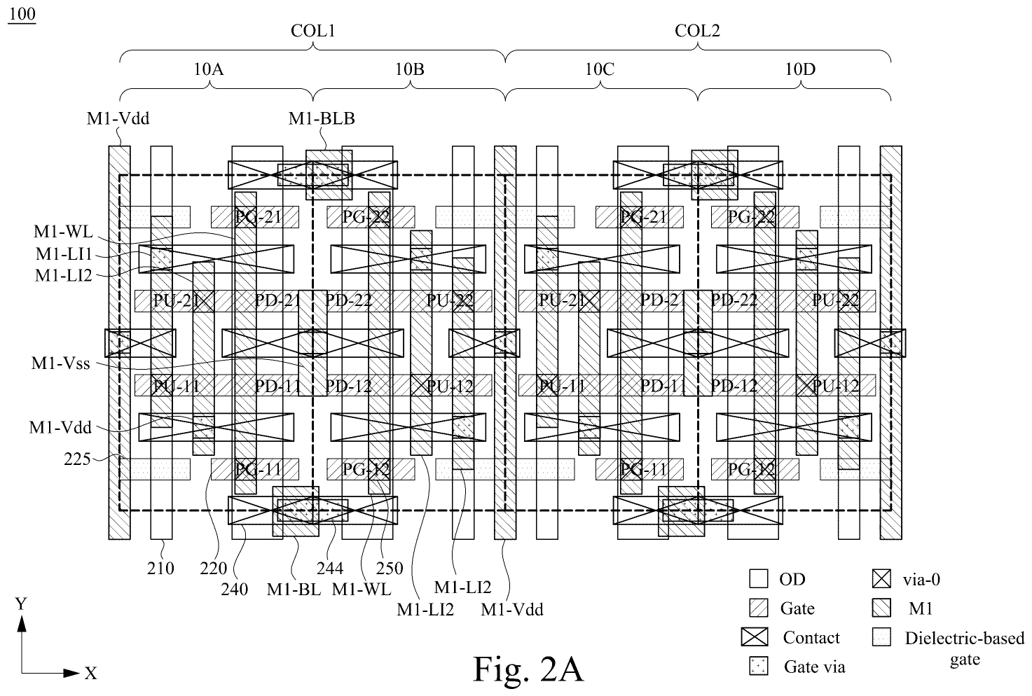

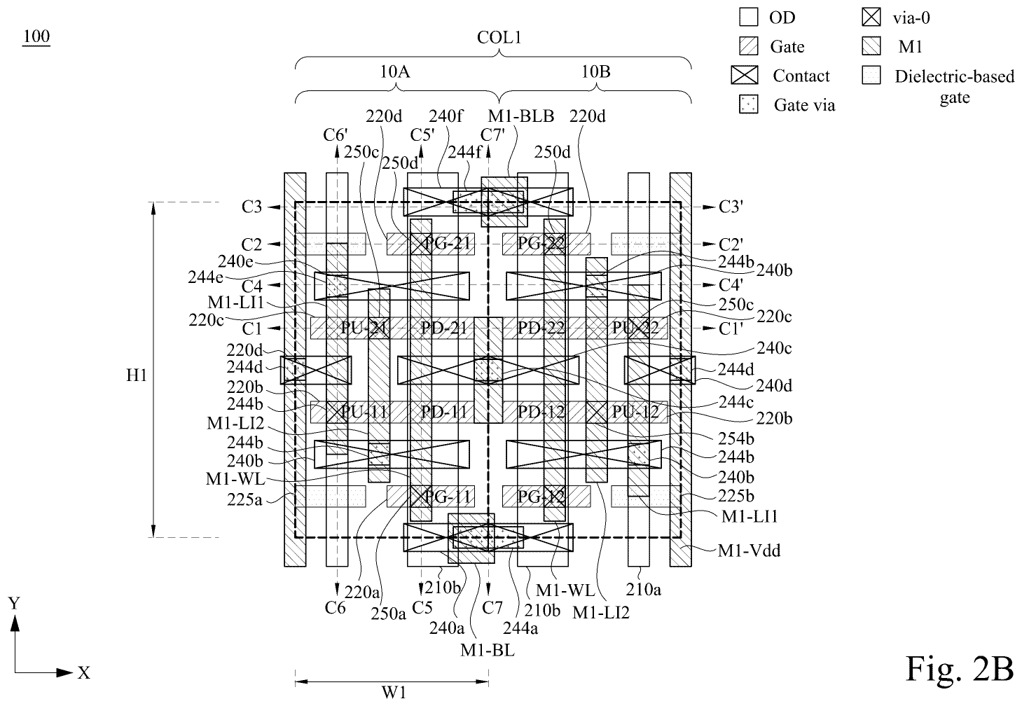

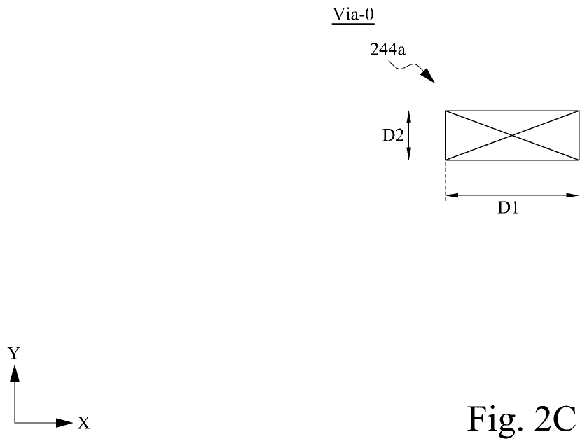

Reference is made to FIG. 2A. FIG. 2A illustrates a layout of a semiconductor structure 100, in accordance with some embodiments. In one or more embodiments of the present disclosure, the semiconductor structure 100 includes a plurality of memory cells 10A, 10B, 10C and 10D arranged in the X-direction. Each of the memory cells 10A, 10B, 10C and 10D corresponds to a single-port SRAM bit cell of the memory cell 10 of FIGS. 1A and 1B. The plurality of memory cells 10A, 10B, 10C and 10D can be implemented in a memory of an IC. The outer boundaries of the memory cells 10A, 10B, 10C and 10D is illustrated using dashed lines. Furthermore, each of the memory cells 10A, 10B, 10C and 10D has a cell weight (or X-pitch) W1 along the X-direction and a cell height (or Y-pitch) H1 along the Y-direction.

In some embodiments, the cell height H1 extends in a word line routing direction (i.e., Y-direction) and a dimension thereof is about 4 times gate pitch (i.e., contacted poly pitch, CPP). By way of example and not limitation, a ratio of the cell weight W1 to the cell height H1 can be in a range from about 1.2 to 2.5, such as about 1.2, 1.5, 1.8, 2.1 or 2.5.

The semiconductor structure 100 may include a plurality of transistors. In some embodiments, the transistors may be GAA FETs. The silicon channel regions of the NMOSFET and PMOSFET transistors are formed by a plurality of semiconductor sheets 210. The semiconductor sheets 210 are stacked along the Z-direction (not shown) and are wrapped by the gate electrode, and the Z-direction is perpendicular to the plane formed by the X-direction and Y-direction. The transistors of the semiconductor structure 100 may include a plurality of gate electrodes 220 over and across the semiconductor sheets 210. The semiconductor sheets 210 may be regarded as a plurality of channel layers 210. The gate electrodes 220 may be used to form the transistors with the semiconductor sheets 210. The gate electrodes 220 are connected to an overlapping metal lines (e.g., metal line M1) through gate vias 250.

In some embodiments, the semiconductor structure 100 may further include dielectric-base gates 225 extending in the X-direction. The gate electrodes 220 extend in the X-direction and being arranged between two of the dielectric-base gates 225 in the X-direction and in the Y-direction. In other words, the gate electrodes 220 extend in parallel with each other, and the dielectric-base gates 225 extend in parallel with a lengthwise direction of the gate electrodes 220. The transistors are between the dielectric-base gates 225. In other words, the dielectric-base gates 225 are formed in the ends of the memory cells 10A, 10B, 10C and 10D, and thus the dielectric-base gates 225 are formed over the boundary of the adjacent two of the memory cells 10A, 10B, 10C and 10D.

In some embodiments, the dielectric-base gates 225 between the adjacent two of the memory cells 10A, 10B, 10C and 10D may be shared by the adjacent two of the memory cells 10A, 10B, 10C and 10D, i.e., the memory cells 10A, 10B, 10C and 10D in the same row are isolated (or separated) from each other by the dielectric-base gate 225. The material of the dielectric-base gates 225 is different from that of the gate electrodes 220. In some embodiments, the dielectric-base gates 225 can be interchangeably referred to dummy gates, dummy gate pattern, dummy gate strip, isolation structures/dielectric gates serving as cell boundaries.

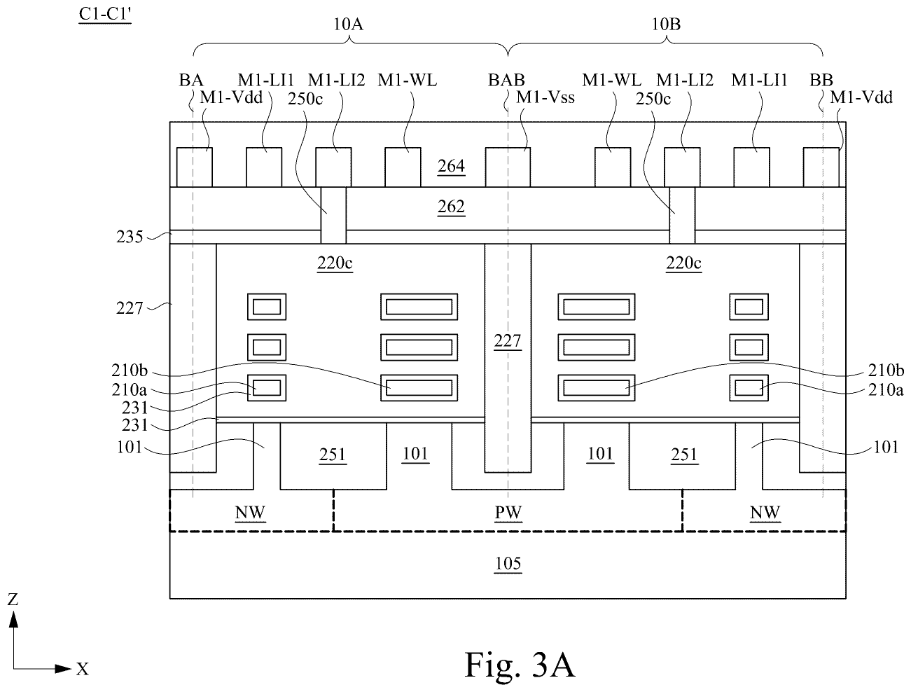

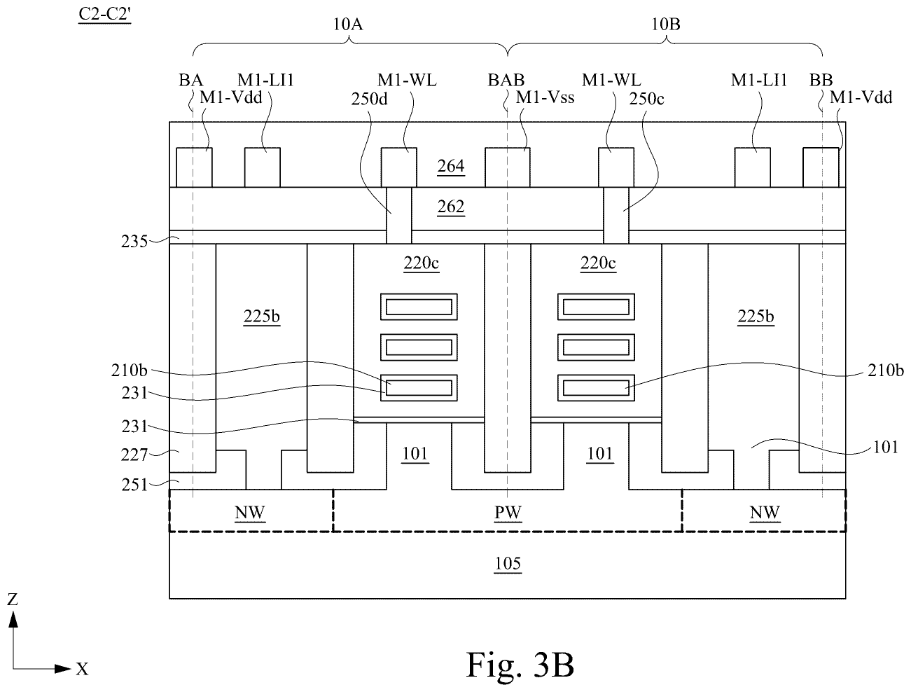

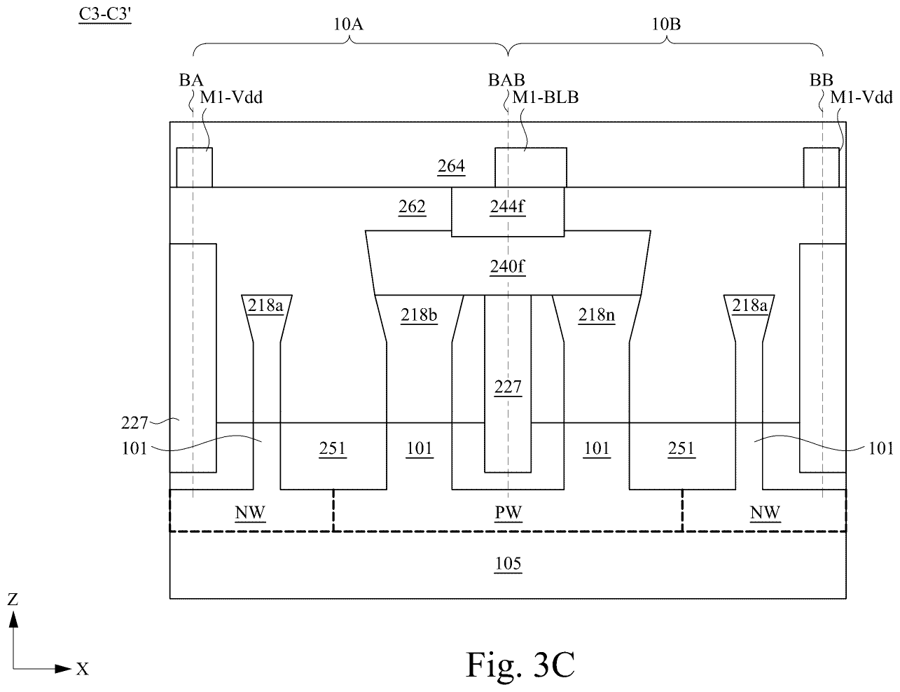

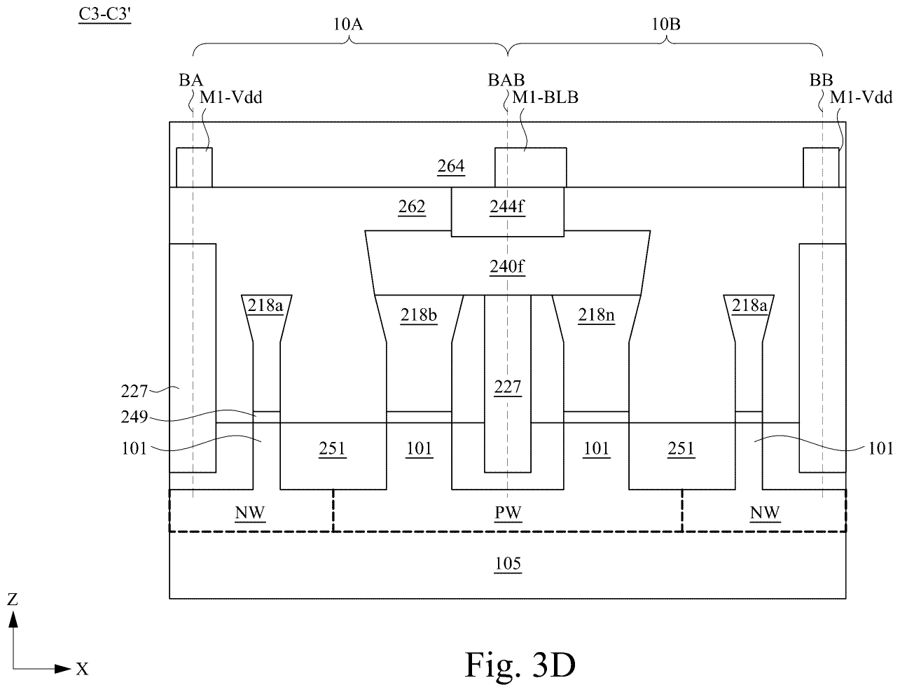

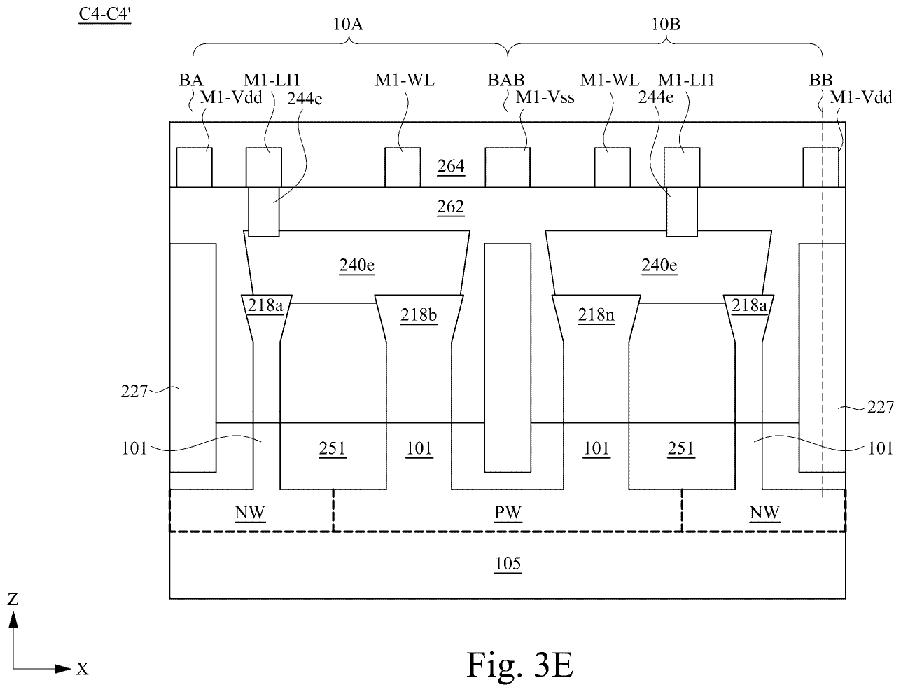

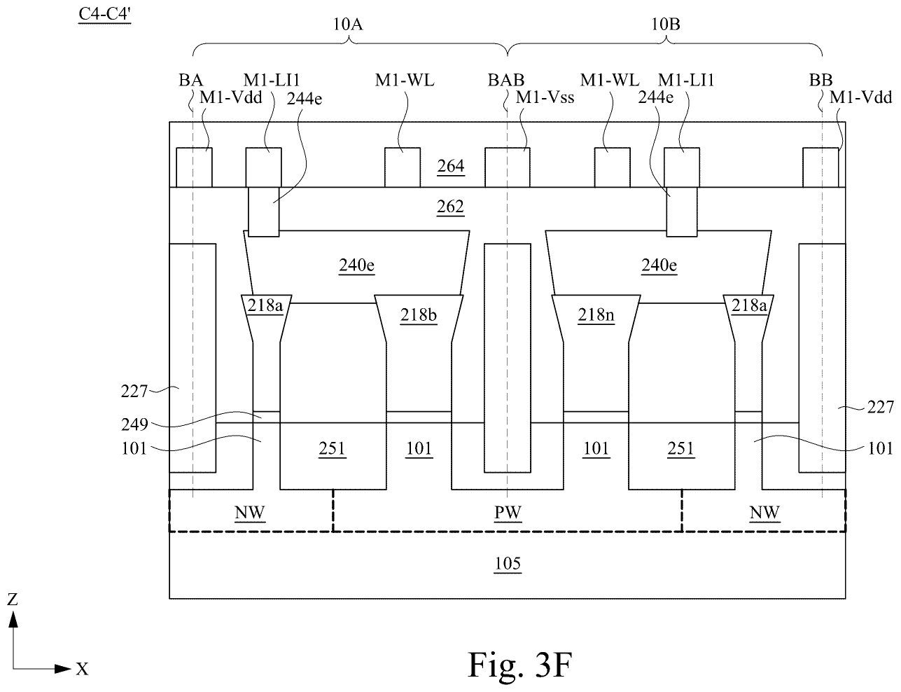

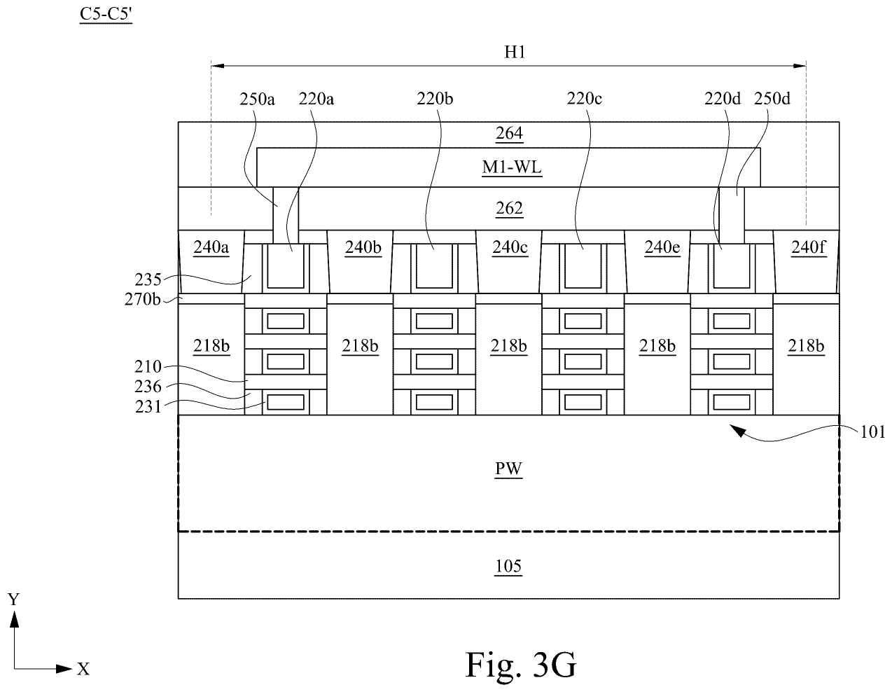

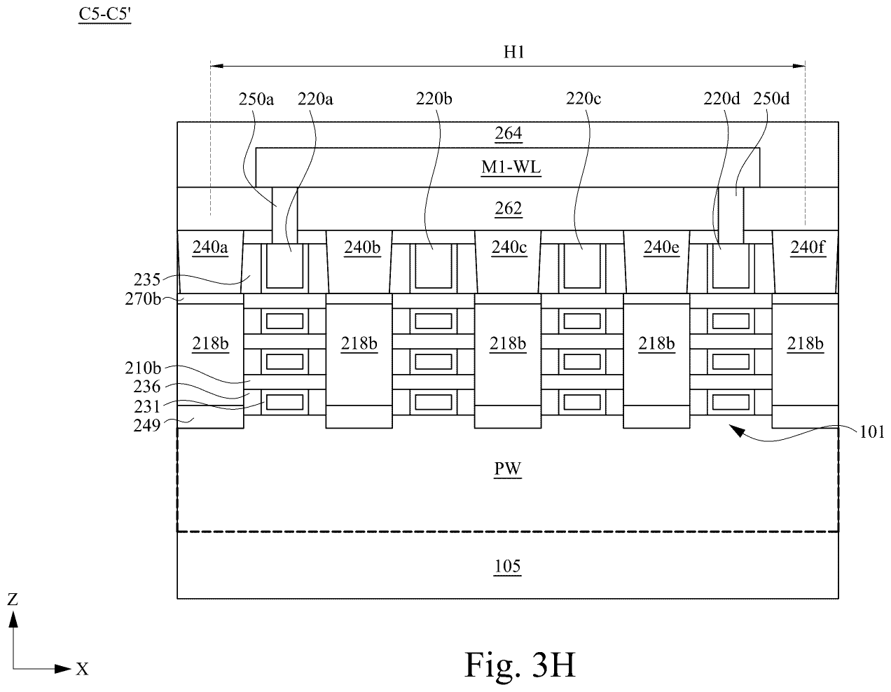

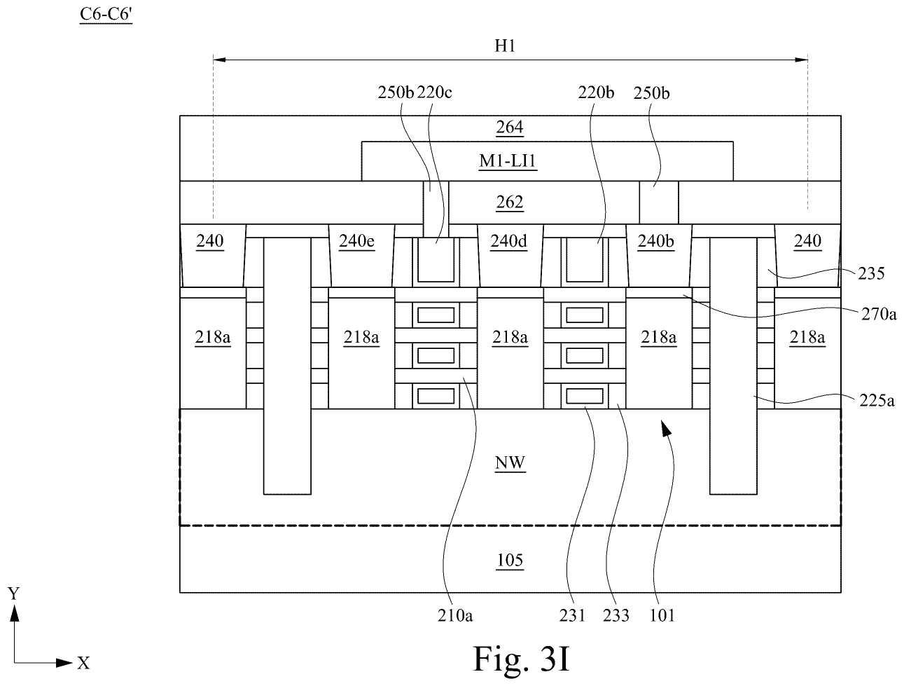

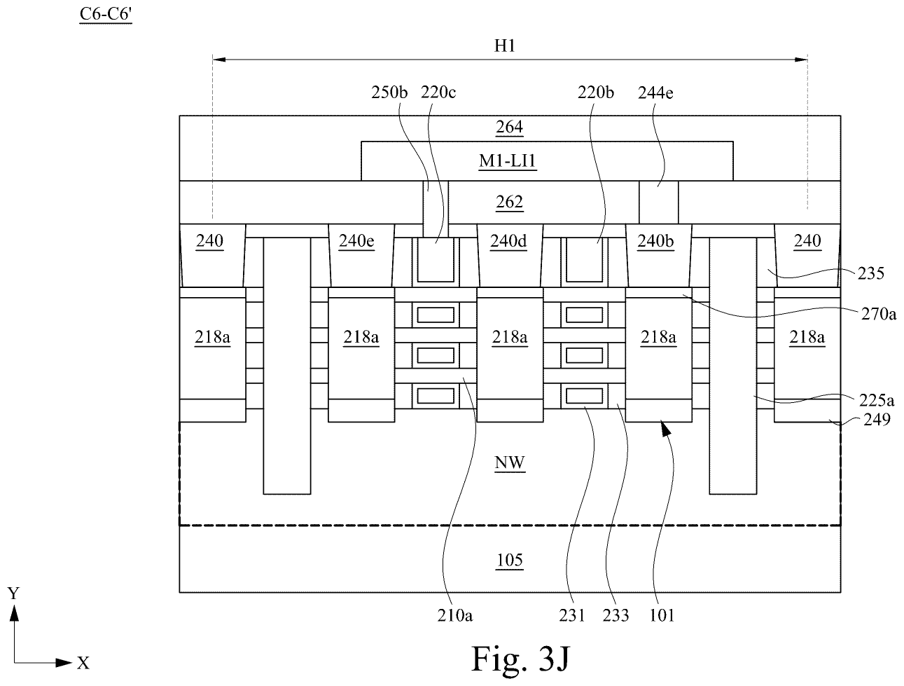

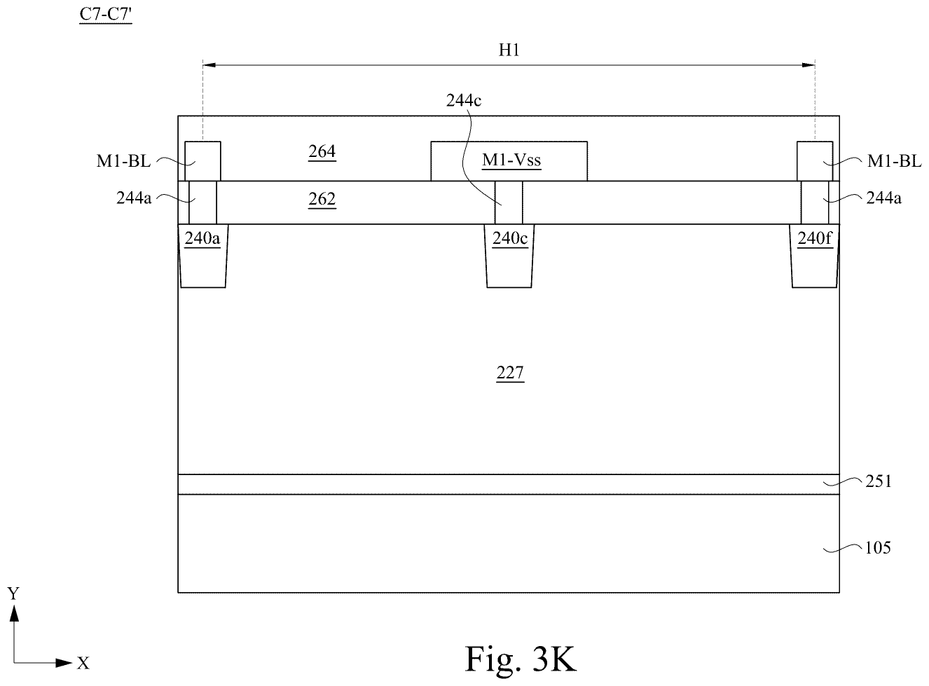

The semiconductor structure 100 may include a plurality of source/drain regions 218 (e.g., source/drain regions 218a/218b as illustrated in FIGS. 3D through 3J) on opposite sides of the semiconductor sheets 210 wrapping around by the gate electrodes 220. In FIG. 2A, a plurality of source/drain contacts 240 may overlap the source/drain regions at opposite sides of the gate electrodes 220. The source/drain contacts 240 may be electrically coupled to a plurality of metal lines M1 through a plurality of contact vias 244. The transistors of the semiconductor structures 100 may include the semiconductor sheets 210, the gate electrodes 220 and the source/drain regions below the source/drain contacts 240.

As illustrated in FIG. 2A, the metal lines M1 may include metal lines M1-Vdd, M1-Vss, M1-LI1, M1-LI2, M1-BL, M1-BLB and M1-WL disposed at the M1 level of the semiconductor structure 100. The metal lines M1-Vdd, M1-Vss, M1-LI1, M1-LI2, M1-BL, M1-BLB and M1-WL disposed at the M1 level of the semiconductor structure may have lengthwise directions parallel to the Y-direction (e.g., column direction).

The metal lines M1-Vdd and M1-Vss are electrically coupled to the source/drain contacts 240 through the contact vias 244. In some embodiments, the power supply voltage metal line M1-Vdd and M1-Vss disposed at the M1 level can be interchangeably referred to a power supply voltage landing pad or a power supply voltage landing line. In some embodiments, the lines can be interchangeably referred to metal layers, conductive lines, conductive layers, or conductors.

In one or more embodiments of the present disclosure, the metal lines M1-Vdd can be interchangeably referred to as a Vdd line that is provided with positive a power supply voltage Vdd. The metal lines M1-Vss can be interchangeably referred to as a Vss line that is provided with power supply voltage Vss. In some embodiments, the cell can be powered through the positive power supply node Vdd that has a positive power supply voltage (also denoted as VDD). The cell can be also connected to power supply voltage Vss (also denoted as VSS), which may be an electrical ground. Throughout the description, the notations of metal lines may be followed by the metal line levels they are in, wherein the respective metal line level is placed in parenthesis.

As shown in FIG. 2A, the metal lines M1-LI1, M1-LI2 and M1-WL are between the metal lines M1-Vdd and M1-Vss. The metal lines M1-LI1 and M1-LI2 are electrically coupled to the source/drain contacts 240 through the contact vias 244 and electrically coupled to the gate electrodes 220 through the gate vias 250. The metal lines M1-BL, M1-BLB and M1-WL are electrically coupled to the source/drain contacts 240 through the contact vias 244.

In FIG. 2A, the memory cells 10A, 10B, 10C and 10D of the semiconductor structure 100 are extended along the Y-direction. The memory cells 10A and 10B may share the same power supply voltage Vss and can be regarded as a column COL1 along Y-direction. The memory cells 10C and 10D may share the same power supply voltage Vss and can be regarded as a column COL2 along Y-direction. The columns COL1 and COL2 of the semiconductor structure 100 are arranged in X-direction. References is made to FIG. 2B to illustrate the column COL1 of the semiconductor structure 100 for illustration the layout as shown in FIG. 2A.

FIG. 2B illustrates the column COL1 of the layout of the semiconductor structure 100 as shown in FIG. 2A, in accordance with some embodiments. As shown in FIG. 2B, the column COL1 may include the memory cells 10A and 10B sharing the same power supply voltage Vss.

As illustrated in FIGS. 2A and 2B, the semiconductor sheets 210 may include semiconductor sheets 210a and 210b extending in the Y-direction. The semiconductor sheets 210b are wider than the semiconductor sheets 210a in the X-direction. The gate electrodes 220 include the gate electrodes 220a, 220b, 220c and 220d extending in the X-direction and parallel with each other. In other words, the memory cells 10A, 10B, 10C and 10D are arranged along a longitudinal direction of the gate electrodes 220, i.e., X-direction in some embodiments. The dielectric-base gates 225 include dielectric-base gates 225a near the boundary BA of the memory cell 10A and dielectric-base gates 225b near the boundary BB of the memory cell 10B. The dielectric-base gates 225a and 225b are parallel to the X-direction. The source/drain contacts 240 overlapping the source/drain regions may include a plurality of source/drain contacts 240a, 240b, 240c, 240d, 240e and 240f parallel to the X-direction and offset from the gate electrodes 220 and dielectric-based gates 225.

In FIG. 2B, the gate vias 250 may include gate vias 250a, 250b, 250c and 250d respectively underlapping and connected to the gate electrodes 220a, 220b, 220c and 220d. The contact vias 244 may include contact vias 244a, 244b, 244c, 244d, 244e and 244f respectively underlapping and connected to the source/drain contacts 240a, 240b, 240c, 240d, 240e and 240f. The metal lines M1 including the metal lines M1-Vdd, M1-Vss, M1-LI1, M1-LI2, M1-BL, M1-BLB and M1-WL are above the gate electrodes 220, the dielectric gates 225 and the source/drain contacts 240.

As illustrated in FIG. 2B, in the memory cell 10A, the gate electrodes 220a, 220b, 220c and 220d may form a plurality of transistors with the semiconductor sheets 210a and 210b. The gate electrode 220a forms a pass-gate transistor PG-11 with the underlying semiconductor sheet 210b. The gate electrode 220b forms a pull-down transistor PD-11 with the underlying semiconductor sheet 210b. The gate electrode 220b forms a pull-up transistor PU-11 with the underlying semiconductor sheet 210a. The gate electrode 220c forms a pull-down transistor PD-21 with the underlying semiconductor sheet 210b. The gate electrode 220c forms a pull-up transistor PU-21 with the underlying semiconductor sheet 210a. The gate electrode 220d forms a pass-gate transistor PG-21 with the underlying semiconductor sheet 210b. The dielectric-based gates 225a are formed over the semiconductor sheet 210a. The pull-up transistors PU-11 and PU-21 are between the dielectric-based gates 225a in the Y-direction. In other words, the transistors PU-11 and PU-21 may share the same semiconductor sheet 210a, and the transistors PG-11, PD-11, PD-21 and PG-21 may share the same semiconductor sheet 210b. The transistors PG-11, PG-21, PD-11, PD-21, PU-11 and PU-21 may respectively correspond to the transistors PG-1, PG-2, PD-1, PD-2, PU-1 and PU-2 of the memory cell 10 as illustrated in FIG. 1B.

The source/drain contact 240a overlaps the semiconductor sheet 201b in the memory cell 10A and thus a source/drain region the pass-gate transistor PG-11 under the source/drain contact 240a is electrically connected to the metal line M1-BL through the source/drain contact 240a and the contact via 244a. Similar to the pass-gate transistor PG-1 as illustrated in FIG. 1B, the pass-gate transistor PG-11 may have the source/drain region electrically coupled to a bit line BL through the metal line M1-BL.

In the memory cell 10A, the source/drain contacts 240b overlap the semiconductor sheet 210a and 210b and thus source/drain regions of the pull-down transistor PD-11 and the pull-up transistor PU-11 under the source/drain contact 240b are electrically connected to the metal line M1-LI2 through the source/drain contact 240b and the contact via 244b. The metal line M1-LI2 is electrically coupled to the gate electrode 220c through the gate via 250c and thus may correspond to a local interconnection routing between the node n2 and the gates of the transistors PU-2 and PD-2. In some embodiments, as illustrated in FIG. 2B, the metal line M1-LI2 extends along Y-direction and overlaps the gate electrodes 220b and 220c.

The source/drain contact 240c overlaps the semiconductor sheet 201b in the memory cell 10A and thus source/drain regions of the pull-down transistors PD-11 and PD-21 under the source/drain contact 240c are electrically connected to the metal line M1-Vss through the source/drain contact 240c and the contact via 244c.

In the memory cell 10A, the source/drain contact 240d overlaps the semiconductor sheet 210a and thus source/drain regions of the pull-up transistors PU-11 and PU-21 under the source/drain contact 240d are electrically connected to the metal line M1-Vdd through the source/drain contact 240d and the contact via 244d.

In the memory cell 10A, the source/drain contacts 240e overlaps the semiconductor sheet 210a and 210b and thus source/drain regions of the pull-down transistor PD-21 and the pull-up transistor PU-21 under the source/drain contact 240e are electrically connected to the metal line M1-LI1 through the source/drain contact 240e and the contact via 244e. The metal line M1-LI1 is electrically coupled to the gate electrode 220b through the gate via 250b and thus may correspond to a local interconnection routing between the node n1 and the gates of the transistors PU-1 and PD-1. In some embodiments, as illustrated in FIG. 2B, the metal line M1-LI1 extends along Y-direction and overlaps the gate electrodes 220b and 220c.

The source/drain contact 240f overlaps the semiconductor sheet 201b in the memory cell 10A and thus a source/drain region the pass-gate transistor PG-21 under the source/drain contact 240f is electrically connected to the metal line M1-BLB through the source/drain contact 240f and the contact via 244f. Similar to the pass-gate transistor PG-2 as illustrated in FIG. 1B, the pass-gate transistor PG-21 may have the source/drain region electrically coupled to a bit line BLB through the metal line M1-BLB.

The metal line M1-WL extends along Y-direction and overlaps the gate electrodes 220a, 220b, 220c and 220d as illustrated in FIG. 2B. The metal line M1-WL is electrically coupled to the gate electrode 220a through the gate via 250a and is electrically coupled to the gate electrode 220d through the gate via 250d, so that gates of the pass-gate transistors PG-11 and PG-21 are electrically coupled to each other through the metal line M1-WL. Similar to the pass-gate transistors PG-1 and PG-2 as illustrated in FIG. 1B, both of the pass-gate transistors PG-11 and PG-21 may have the gates electrically coupled to a word line WL through the metal line M1-WL.

Reference is made to FIG. 1B and FIG. 2B. Similar to the memory cell 10 as illustrated in FIG. 1B, in the memory cell 10A shown in FIG. 2B, the gates of the pass-gate transistors PG-11 and PG-21 may be electrically coupled to the word line WL through the metal line M1-WL. One of the source/drain region of the pass-gate transistor PG-11 may be electrically coupled to the bit line BL through the source/drain contact 240a, the contact via 244a and the metal line M1-BL and another one of the source/drain region of the pass-gate transistor PG-11 may be electrically coupled to source/drain regions of the pull-up transistor PU-11 and pull-down transistor PU-11 through the source/drain contact 240b overlying the semiconductor sheets 210a and 210b. One of the source/drain region of the pass-gate transistor PG-21 may be electrically coupled to the bit line BLB through the source/drain contact 240f, the contact via 244f and the metal line M1-BLB and another one of the source/drain region of the pass-gate transistor PG-21 may be electrically coupled to source/drain regions of the pull-up transistor PU-21 and pull-down transistor PU-21 through the source/drain contact 240f overlying the semiconductor sheets 210a and 210b. The common source/drain contact 240b of the pull-up transistor PU-11 and pull-down transistor PU-11 may be electrically coupled to the common gate electrode 220c of the pull-up transistor PU-21 and pull-down transistor PU-21 through the metal line M1-LI2. The common source/drain contact 240e of the pull-up transistor PU-21 and pull-down transistor PU-21 may be electrically coupled to the common gate electrode 220b of the pull-up transistor PU-11 and pull-down transistor PU-11 through the metal line M1-LI1. The metal line M1-Vdd for a power supply VDD may be electrically connected to the common source/drain contact 240d of the pull-up transistors PU-11 and PU-21 through the contact via 244d. The metal line M1-Vss for a ground VSS may be electrically connected to the common source/drain contact 240c of the pull-down transistors PD-11 and PD-21 through the contact via 244d.

As illustrated in FIG. 2B, in the memory cell 10B, the gate electrodes 220a, 220b, 220c and 220d may form a plurality of transistors with the semiconductor sheets 210a and 210b. The gate electrode 220a forms a pass-gate transistor PG-12 with the underlying semiconductor sheet 210b. The gate electrode 220b forms a pull-down transistor PD-12 with the underlying semiconductor sheet 210b. The gate electrode 220b forms a pull-up transistor PU-12 with the underlying semiconductor sheet 210a. The gate electrode 220c forms a pull-down transistor PD-22 with the underlying semiconductor sheet 210b. The gate electrode 220c forms a pull-up transistor PU-22 with the underlying semiconductor sheet 210a. The gate electrode 220d forms a pass-gate transistor PG-22 with the underlying semiconductor sheet 210b. The dielectric-based gates 225b are formed over the semiconductor sheet 210a. The pull-up transistors PU-12 and PU-22 are between the dielectric-based gates 225b in the Y-direction. In other words, the transistors PU-12 and PU-22 may share the same semiconductor sheet 210a, and the transistors PG-12, PD-12, PD-22 and PG-22 may share the same semiconductor sheet 210b. The transistors PG-12, PG-22, PD-12, PD-22, PU-12 and PU-22 may respectively correspond to the transistors PG-1, PG-2, PD-1, PD-2, PU-1 and PU-2 of the memory cell 10 as illustrated in FIG. 1B.

The source/drain contact 240a overlaps the semiconductor sheet 201b in the memory cell 10B and thus a source/drain region the pass-gate transistor PG-12 under the source/drain contact 240a is electrically connected to the metal line M1-BL through the source/drain contact 240a and the contact via 244a. Similar to the pass-gate transistor PG-1 as illustrated in FIG. 1B, the pass-gate transistor PG-12 may have the source/drain region electrically coupled to a bit line BL through the metal line M1-BL.

In the memory cell 10B, the source/drain contacts 240b overlaps the semiconductor sheet 210a and 210b and thus source/drain regions of the pull-down transistor PD-12 and the pull-up transistor PU-12 under the source/drain contact 240b are electrically connected to the metal line M1-LI2 through the source/drain contact 240b and the contact via 244b. The metal line M1-LI2 is electrically coupled to the gate electrode 220c through the gate via 250c and thus may correspond to a local interconnection routing between the node n2 and the gates of the transistors PU-2 and PD-2. In some embodiments, as illustrated in FIG. 2B, the metal line M1-LI2 extends along Y-direction and overlaps the gate electrodes 220b and 220c.

The source/drain contact 240c overlaps the semiconductor sheet 201b in the memory cell 10B and thus source/drain regions of the pull-down transistors PD-12 and PD-22 under the source/drain contact 240c are electrically connected to the metal line M1-Vss through the source/drain contact 240c and the contact via 244c.

In the memory cell 10B, the source/drain contact 240d overlaps the semiconductor sheet 210a and thus source/drain regions of the pull-up transistors PU-12 and PU-22 under the source/drain contact 240d are electrically connected to the metal line M1-Vdd through the source/drain contact 240d and the contact via 244d.

In the memory cell 10B, the source/drain contacts 240e overlaps the semiconductor sheet 210a and 210b and thus source/drain regions of the pull-down transistor PD-22 and the pull-up transistor PU-22 under the source/drain contact 240e are electrically connected to the metal line M1-LI1 through the source/drain contact 240e and the contact via 244e. The metal line M1-LI1 is electrically coupled to the gate electrode 220b through the gate via 250b and thus may correspond to a local interconnection routing between the node n1 and the gates of the transistors PU-1 and PD-1. In some embodiments, as illustrated in FIG. 2B, the metal line M1-LI1 extends along Y-direction and overlaps the gate electrodes 220b and 220c.

The source/drain contact 240f overlaps the semiconductor sheet 201b in the memory cell 10B and thus a source/drain region the pass-gate transistor PG-22 under the source/drain contact 240f is electrically connected to the metal line M1-BLB through the source/drain contact 240f and the contact via 244f. Similar to the pass-gate transistor PG-2 as illustrated in FIG. 1B, the pass-gate transistor PG-22 may have the source/drain region electrically coupled to a bit line BLB through the metal line M1-BLB.

The metal line M1-WL extends along Y-direction and overlaps the gate electrodes 220a, 220b, 220c and 220d as illustrated in FIG. 2B. The metal line M1-WL is electrically coupled to the gate electrode 220a through the gate via 250a and is electrically coupled to the gate electrode 220d through the gate via 250d, so that gates of the pass-gate transistors PG-12 and PG-22 are electrically coupled to each other through the metal line M1-WL. Similar to the pass-gate transistors PG-1 and PG-2 as illustrated in FIG. 1B, both of the pass-gate transistors PG-12 and PG-22 may have the gates electrically coupled to a word line WL through the metal line M1-WL.

Reference is made to FIG. 1B and FIG. 2B. Similar to the memory cell 10 as illustrated in FIG. 1B, in the memory cell 10B shown in FIG. 2B, the gates of the pass-gate transistors PG-12 and PG-22 may be electrically coupled to the word line WL through the metal line M1-WL. One of the source/drain region of the pass-gate transistor PG-12 may be electrically coupled to the bit line BL through the source/drain contact 240a, the contact via 244a and the metal line M1-BL and another one of the source/drain region of the pass-gate transistor PG-12 may be electrically coupled to source/drain regions of the pull-up transistor PU-12 and pull-down transistor PU-12 through the source/drain contact 240b overlying the semiconductor sheets 210a and 210b. One of the source/drain region of the pass-gate transistor PG-22 may be electrically coupled to the bit line BLB through the source/drain contact 240f, the contact via 244f and the metal line M1-BLB and another one of the source/drain region of the pass-gate transistor PG-22 may be electrically coupled to source/drain regions of the pull-up transistor PU-22 and pull-down transistor PU-22 through the source/drain contact 240f overlying the semiconductor sheets 210a and 210b. The common source/drain contact 240b of the pull-up transistor PU-12 and pull-down transistor PU-12 may be electrically coupled to the common gate electrode 220c of the pull-up transistor PU-22 and pull-down transistor PU-22 through the metal line M1-LI2. The common source/drain contact 240e of the pull-up transistor PU-22 and pull-down transistor PU-22 may be electrically coupled to the common gate electrode 220b of the pull-up transistor PU-12 and pull-down transistor PU-12 through the metal line M1-LI1. The metal line M1-Vdd for a power supply VDD may be electrically connected to the common source/drain contact 240d of the pull-up transistors PU-12 and PU-22 through the contact via 244d. The metal line M1-Vss for a ground VSS may be electrically connected to the common source/drain contact 240c of the pull-down transistors PD-12 and PD-22 through the contact via 244d.

As illustrated in FIG. 2B, the source/drain contacts 240a, 240c and 240f extend along the X-direction and across the memory cells 10A and 10B. In other words, the memory cells 10A and 10B may share the same the source/drain contacts 240a, 240c and 240f. The contact vias 244a, 244c and 244f respectively over the source/drain contacts 240a, 240c and 240f may also have long-slot profiles extending across the memory cells 10A and 10B. The contact via 244c is shared by the memory cells 10A and 10B so that the memory cells 10A and 10B may share the same ground VSS. The contact via 244a coupled to the metal line M1-BL and the contact via 244f coupled to the metal line M1-BLB are shared by the memory cells 10A and 10B so that the memory cells 10A and 10B may share the same pair of the bit lines BL and BLB.

In some embodiments, since the contact vias 244a and 244f have great top view area, the contact via 244a is partially overlapped by the metal line M1-BL, and the contact via 244f is partially overlapped by the metal line M1-BLB.

As shown in FIGS. 2A and 2B, the contact via 244a over the common source/drain contact 240a and under the metal line M1-BL can have a great top view area. FIG. 2C illustrates an example top view of the contact via 244a, in accordance with some embodiments. The contact via 244a can extend along a lengthwise direction of the gate electrodes 220. Specifically, the contact via 244a overlapping the common source/drain contact 240a may have a dimension D1 extending in the X-direction and a dimension D2 extending in the Y-direction. In some embodiments, a ratio of the dimension D1 to the dimension D2 can be in a range from about 2 to 5, such as about 2, 2.5, 3, 3.5, 4, 4.5 or 5. In some embodiments, the contact via 244f overlapping the common source/drain contact 240f may have may have a dimension D1 in the X-direction and a dimension D2 extending in the Y-direction, and the ratio of the dimension D1 to the dimension D2 of the contact via 244f can be in a range from about 2 to 5, such as about 2, 2.5, 3, 3.5, 4, 4.5 or 5. The increased areas of the contact via 244a at the interconnect via via-0 level can facilitate improved electrical connection between the SRAM cells.

Reference is made to FIGS. 2A and 2B. As illustrated in FIG. 2A, the source/drain contact 240c in the memory cell 10B extends in X-direction and overlying the memory cell 10C, and the source/drain contact 240c may be electrically coupled to the metal line M1-Vdd through the contact via 244c. On the other words, the memory cells 10B and 10C may share the same power supply VDD.

As illustrated in FIG. 2A, the memory cell 10C may include pass-gate transistors PU-11 and PU-21, pull-up transistors PU-11 and PU-21 and pull-down transistors PD-11 and PD-21. In one or more embodiments of the present disclosure, the arrangements of the pass-gate transistors PU-11 and PU-21, the pull-up transistors PU-11 and PU-21 and the pull-down transistors PD-11 and PD-21 in the memory cell 10C may be similar to the arrangements of the pass-gate transistors PU-11 and PU-21, the pull-up transistors PU-11 and PU-21 and the pull-down transistors PD-11 and PD-21 in the memory cell 10A. The memory cell 10D may include pass-gate transistors PU-12 and PU-22, pull-up transistors PU-12 and PU-22 and pull-down transistors PD-12 and PD-22. In one or more embodiments of the present disclosure, the arrangements of the pass-gate transistors PU-12 and PU-22, the pull-up transistors PU-12 and PU-22 and the pull-down transistors PD-12 and PD-22 in the memory cell 10D may be similar to the arrangements of the pass-gate transistors PU-12 and PU-22, the pull-up transistors PU-12 and PU-22 and the pull-down transistors PD-12 and PD-22 in the memory cell 10B. The memory cells 10C and 10D may share the same bit-line pair.

Reference is made to FIGS. 2B and 3A-3J. FIGS. 3A through 3J illustrate cross-sectional views obtained from reference cross-sections C1-C1′, C2-C2′, C3-C3′, C4-C4′, C5-C5′, C6-C6′ and C7-C7 in FIG. 2B.

FIG. 3A illustrates the cross-section view obtained from the reference cross-section C1-C1′, which is parallel to X-direction and across the pull-up transistor PU-21 and pull-down transistor PD-21 in the memory cell 10A and the pull-up transistor PU-22 and pull-down transistor PD-22 in the memory cell 10B.

Reference is made to FIGS. 2B and 3A. N-type well regions NW and a p-type well region PW are formed over a semiconductor substrate 105. The n-type well regions NW are formed respectively near the boundary BA of the memory cell 10A and near the boundary BB of the memory cell 10B in the X-direction. The p-type well region PW is formed between the n-type well regions NW and extends across the boundary of the memory cells 10A and 10B. The semiconductor sheets 210a are formed over the n-type well regions NW and arranged in the Z-direction. The semiconductor sheets 210b are formed over the p-type well region PW and arranged in the Z-direction.

A plurality of fin strips 101 is semiconductor strip patterned in the substrate 105. A shallow trench isolation (STI) structure 251 can be formed over the substrate 105 and laterally surround the fin strip 101. In some embodiments, the top surface of the STI structure 251 is coplanar with a top surface of the fin strip 101. In some embodiments, the top surface of the STI structure 251 is above or below the top surface of the fin strip 101. In some embodiments, the STI structure 251 may separate the features of adjacent devices. A plurality of shallow trench isolation (STI) structures 251 is formed between the semiconductor sheets 210a and 210b.

The semiconductor sheets 210 including the semiconductor sheets 210a and 210b may be regarded as channel layers 210 stacked along the Z-direction over the fin strip 101 and acting as active regions. A plurality of gate dielectric layers 231 are formed over the fin strips 101 and wrap around the semiconductor sheets 210a and 210b. In the memory cell 10A, the semiconductor sheets 210a are wrapped by the gate electrode 220c with the gate dielectric layers 231 to form the pull-up transistor PU-21, and the semiconductor sheets 210b are wrapped by the gate electrode 220c with the gate dielectric layers 231 form the pull-down transistor PD-21. In the memory cell 10B, the semiconductor sheets 210a are wrapped by the gate electrode 220c with the gate dielectric layers 231 to form the pull-up transistor PU-22, and the semiconductor sheets 210b are wrapped by the gate electrode 220c with the gate dielectric layers 231 form the pull-down transistor PD-22. A plurality of dielectric regions 227 are formed on the boundaries BA, BAB and BB and used as gate ends of the separated gate electrodes 220c in the memory cells 10A and 10B.

In some embodiments, each dielectric region 227 is a gate-cut structure for the gate structure, and the gate-cut structure is formed by a cut metal gate (CMG) process. In some embodiments, the dielectric region 227 may be made of dielectric material. In some embodiments, the dielectric regions 227 may be formed of or comprise SiO₂, SiOC, SiOCN, or the like, or combinations thereof. In some embodiments, the dielectric regions 227 may be made of a nitride-based material, such as Si₃N₄, or a carbon-based material, such as SiOCN, or combinations thereof. In some embodiments, the dielectric regions 227 may be made of a metal oxide material. In some embodiments, the dielectric regions 227 may be made of a material having a dielectric constant greater than about 9 (e.g., high dielectric constant (high-k) material). For example, the dielectric regions 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 227 may be formed of a homogenous material, or may have a composite structure including more than one layer. In some embodiments, the dielectric regions 227 may include dielectric liners, which may be formed of, for example, silicon oxide.

In some embodiments, hard mask layers 235 are formed over the gate electrode 220c. In some embodiments, the hard mask layer 235 can be interchangeably referred to a gate top dielectric. In some embodiments, the hard mask layer 235 is made of a different material than the dielectric region 227. In some embodiments, the hard mask layer 235 may be made of dielectric material, such as SiO₂, Si₃N₄, SiON, SiOC, SiOCN base dielectric material, or combinations thereof.

In FIG. 3A, an inter-layer dielectric (ILD) layer 262 is formed over the hard mask layers 235. An inter-metal dielectric (IMD) layer 264 is formed over the ILD layer 262 and can provide electrical insulation as well as structural support for the various features therein, such as the metal line M1 including the metal lines M1-Vdd, M1-Vss, M1-LI1, M1-LI2 and M1-WL. In some embodiments, the ILD layer 262 and/or the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

The gate vias 250 are formed to pass through the ILD layer 262 and the hard mask layer 235 and land on the gate electrodes 220. In some embodiments, the gate vias 250 may include a metal-containing material such as titanium nitride, titanium oxide, tungsten, cobalt, ruthenium, aluminum, copper, combinations thereof, multi-layers thereof, or the like. As illustrated in FIG. 3A, the gate vias 250c are formed to pass through the ILD layer 262 and the hard mask layer 235 and land on the gate electrode 220c in the memory cells 10A and 10B.

FIG. 3B illustrates the cross-section view obtained from the reference cross-section C2-C2′, which is parallel to X-direction and across the dielectric-based gate 225a, the pass-gate transistor PG-21 in the memory cell 10A, the pass-gate transistor PG-22 in the memory cell 10B and the dielectric-base gate 225b.

Reference is made to FIGS. 2B and 3B. The semiconductor sheets 210b over the p-type well regions NW in the memory cell 10A is wrapped by the gate electrode 220d with the gate dielectric layer 231 to form the pass-gate transistor PG-21. The semiconductor sheets 210b over the p-type well regions NW in the memory cell 10B is wrapped by the gate electrode 220d with the gate dielectric layer 231 to form the pass-gate transistor PG-22. As illustrated in FIG. 3B, the semiconductor sheets 210a over the n-type well regions NW in the memory cell 10A is removed to form the dielectric-based gate 225a, and the semiconductor sheets 210a over the n-type well regions NW in the memory cell 10B is removed to form the dielectric-based gate 225b. The gate electrodes 220d are electrically coupled to the metal lines M1-W1 by the gate vias 250d passing through the ILD layer 262 and the hard mask layer 235. In FIG. 3B, the dielectric regions 227 are formed between the gate electrodes 220d and the dielectric-based gates 225a and 225b.

FIG. 3C illustrates the cross-section view obtained from the reference cross-section C3-C3′, which is parallel to X-direction and across the common source/drain contacts 240f of the memory cells 10A and 10B.

Reference is made to FIGS. 2B and 3C. Source/drain regions 218a are formed over the semiconductor sheets 210a over the n-type well region NW. Source/drain regions 218b are formed over the semiconductor sheets 210b over the p-type well region PW. In some embodiments, a dopant in the source/drain regions 218a over the n-type well regions NW has an opposite conductivity type to another dopant in the source/drain regions 218b over the p-type well regions PW. The source/drain regions 218a may have a p-type dopant. The source/drain regions 218b over the p-type well regions PW may have an n-type dopant. The source/drain regions 218b may be the source/drain regions of the pass-gate transistors PG-21 and PG-22.

In some embodiments, the n-type source/drain regions 218b may include SiP, SiC, SiPC, SiAs, Si, or a combination thereof. In some embodiments, the n-type source/drain regions 218b may have a phosphorus concentration within a range from about 2E19/cm³ to about 3E21/cm³. In some embodiments, the p-type source/drain regions 218a may include boron, BF₂, SiGe, or a combination thereof. In some embodiments, the p-type source/drain regions 218a may have a boron concentration within a range from about 1E19/cm³ to about 6E20/cm³. In some embodiments, the p-type source/drain regions 218a may have a Ge atomic percentage within a range of about 36% to about 85%. In some embodiments, 218a having the p-type dopant may include a carbon-containing material.

The ILD layer 262 is formed between the gate electrode 220 and over the source/drain regions 218a and 218b. The IMD layer 264 is formed over the ILD layer 262. In FIG. 3C, the source/drain regions 218a are free from the metal lines M1 in the IMD layer 264. The source/drain contact 240f overlaps the source/drain regions 218b in the memory cells 10A and 10B and extends across the memory cells 10A and 10B. In FIG. 3C, the source/drain contact 240f overlaps the dielectric region 227 at the boundary BAD and between the source/drain regions 218b. The common source/drain contact 240f is connected to the metal line M1-BLB through the contact via 244f in the ILD layer 262. In some embodiments, a portion of the contact via 244f extends into the source/drain contact 240f.

FIG. 3D illustrates the cross-section view obtained from the reference cross-section C3-C3′, in accordance with some embodiments. A difference between the structures of FIGS. 3C and 3D includes that the dielectric layers 249 may be formed between the source/drain regions 218a/218b and the fin strips. In some embodiments, the dielectric layer 249 can be interchangeably referred to a dielectric barrier layer or a leakage barrier for reducing leakage current.

FIG. 3E illustrates the cross-section view obtained from the reference cross-section C4-C4′, which is parallel to X-direction and across the source/drain contact 240e in the memory cell 10A and the source/drain contact 240e in the memory cell 10B.

Reference is made to FIGS. 2B and 3E. In FIG. 3E, the source/drain regions 218a may be the source/drain regions of the pull-up transistors PU-21 and PU-22, and the source/drain regions 218b may include a common source/drain region of the pass-gate transistor PG-21 and the pull-down transistor PD-21 in the memory cell 10A and a common source/drain region of the pass-gate transistor PG-22 and the pull-down transistor PD-22 in the memory cell 10B. In the memory cells 10A and 10B, the adjacent source/drain regions 218a and 218b are connected to each other by the source/drain contacts 240e overlying the source/drain regions 218a and 218b. The source/drain contacts 240e in the memory cells 10A and 10B are separated from each other by the dielectric region 227 on the boundary BAB of the memory cells 10A and 10B. The source/drain contacts 240e may be electrically coupled to the metal lines M1-LI1 through the contact vias 244e.

FIG. 3F illustrates the cross-section view obtained from the reference cross-section C4-C4′, in accordance with some embodiments. A difference between the structures of FIGS. 3E and 3F includes that the dielectric layers 249 for reducing leakage current may be formed between the source/drain regions 218a/218b and the fin strips 101.

FIG. 3G illustrates the cross-section view obtained from the reference cross-section C5-C5′, which is parallel to Y-direction and along the semiconductor sheet 210b in the memory cell 10A.

Reference is made to FIGS. 2B and 3G. The gate electrode 220a wraps around the semiconductor sheets 210b to form the pass-gate transistor PG-11 with the source/drain regions 218b on opposite sides of the semiconductor sheets 210b under the gate electrode 220a. The gate electrode 220b wraps around the semiconductor sheets 210b to form the pull-down transistor PD-11 with the source/drain regions 218b on opposite sides of the semiconductor sheets 210b under the gate electrode 220b. The gate electrode 220c wraps around the semiconductor sheets 210b to form the pull-down transistor PD-21 with the source/drain regions 218b on opposite sides of the semiconductor sheets 210b under the gate electrode 220c. The gate electrode 220d wraps around the semiconductor sheets 210b to form the pass-gate transistor PG-21 with the source/drain regions 218b on opposite sides of the semiconductor sheets 210b under the gate electrode 220d. The gate electrode 220a is electrically coupled to the metal line M1-WL through the gate via 250a. The gate electrode 220d is electrically coupled to the metal line M1-WL through the gate via 250d.

In FIG. 3G, gate spacers 233 are formed on the sidewalls of the gate electrodes 220 such as the gate electrodes 220a, 220b, 220c and 220d with the gate dielectric layers 231. In some embodiments, the gate spacer 233 may be made of silicon nitride or silicon oxynitride, although any suitable material, such as low-dielectric constant (low-k) materials having a k-value less than about 3.5, may be utilized. Inner spacers 236 can act as isolation features and may be formed between the source/drain regions 218b and the gate electrodes 220. In some embodiments, the inner spacers 236 can be interchangeably referred to lower gate spacers. In some embodiments, the inner spacers 236 may have a lateral dimension in a range from about 4 nm to about 12 nm. In some embodiments, the inner spacers 236 may be made of silicon nitride or silicon oxynitride, although any suitable material, such as low-dielectric constant (low-k) materials having a k-value less than about 3.5, may be utilized. In some embodiments, the inner spacers 236 may be air gaps. In some embodiments, the inner spacer 236 may have a higher K (dielectric constant) value than the gate spacer 233. In some embodiments, the hard mask layers 235 are formed over the gate electrode layers 220. In some embodiments, the hard mask layer 235 can be interchangeably referred to a gate top dielectric. In some embodiments, the hard mask layer 235 is made of a different material than the dielectric regions 227.

In some embodiments, silicide regions 270b are formed between the source/drain contacts 240a/240b/240c/240e/240f and the source/drain regions 218b for Rc reduction. In some embodiments, a metal silicidation process can be performed on the source/drain region 218b to form the silicide region 270b.

FIG. 3H illustrates the cross-section view obtained from the reference cross-section C5-C5′, in accordance with some embodiments. A difference between the structures of FIGS. 3G and 3H may include that the dielectric layers 249 for reducing leakage current may be formed between the source/drain regions 218b and the fin strips 101.

FIG. 3I illustrates the cross-section view obtained from the reference cross-section C6-C6′, which is parallel to Y-direction and along the semiconductor sheet 210a in the memory cell 10A.

Reference is made to FIGS. 2B and 3I. The gate electrode 220b wraps around the semiconductor sheets 210a to form the pull-up transistor PU-11 with the source/drain regions 218a on opposite sides of the semiconductor sheets 210a under the gate electrode 220b. The gate electrode 220b is electrically connected to the metal line M1-LI1 through the gate via 250b. The gate electrode 220c wraps around the semiconductor sheets 210a to form the pull-up transistor PU-21 with the source/drain regions 218a on opposite sides of the semiconductor sheets 210a under the gate electrode 220c. The source/drain contact 240e is electrically connected to the metal line M1-LI1 through the contact via 244e.

In FIGS. 2B and 3I, the dielectric-based gates 225a are formed for cell isolation. Each dielectric-based gate 225a extends through a stack of the semiconductor sheets 210a and between the inner spacers 236. For illustration, the source/drain contacts 240 out of the two adjacent dielectric-based gates 225a in the memory cell 10A are omitted in FIG. 2B. In some embodiments, the hard mask layers 235 are formed over the dielectric-based gates 225a.

In some embodiments, silicide regions 270a are formed between the source/drain contacts 240b/240f/240e and the source/drain regions 218a for Rc reduction. In some embodiments, a metal silicidation process can be performed on the source/drain region 218a to form the silicide region 270a.

In some embodiments, a metal silicidation process can be performed on the source/drain region 218a/218b to form the silicide region 270a/270b. The metal silicidation process is to make a reaction between metal and silicon (or polycrystalline silicon). In some embodiments, a metal layer is formed on the source/drain region 218a/218b. Subsequently, regarding the metal silicidation process, a first rapid thermal annealing (RTA) process may be performed in, for example, Ar, He, N₂ or other inert atmosphere at a first temperature, such as lower than 200˜300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500° C., thereby forming a silicide region 270a/270b with low resistance. In some embodiments, the silicide region 270a/270b may include titanium silicide (TiSi), TiSi₂, nickel silicide (NiSi), PtSi, MoSi, MOSi₂, cobalt silicide (CoSi), CoSi₂, Ni—Pt, or combinations thereof.

FIG. 3J illustrates the cross-section view obtained from the reference cross-section C6-C6′, in accordance with some embodiments. A difference between the structures of FIGS. 31 and 3J includes that the dielectric layers 249 for reducing leakage current may be formed between the source/drain regions 218a and the fin strips 101.

FIG. 3K illustrates the cross-section view obtained from the reference cross-section C7-C7′, which is parallel to Y-direction and along the boundary of the memory cells 10A and 10B.

Reference is made to FIGS. 2B and 3K. The source/drain contacts 240a, 240c and 240f extend over the dielectric region 227. The source/drain contact 240a is electrically coupled to the metal line M1-BL through the contact via 244a. The source/drain contact 240c is electrically coupled to the metal line M1-Vss through the contact via 244c. The source/drain contact 240f is electrically coupled to the metal line M1-BLB through the contact via 244f.

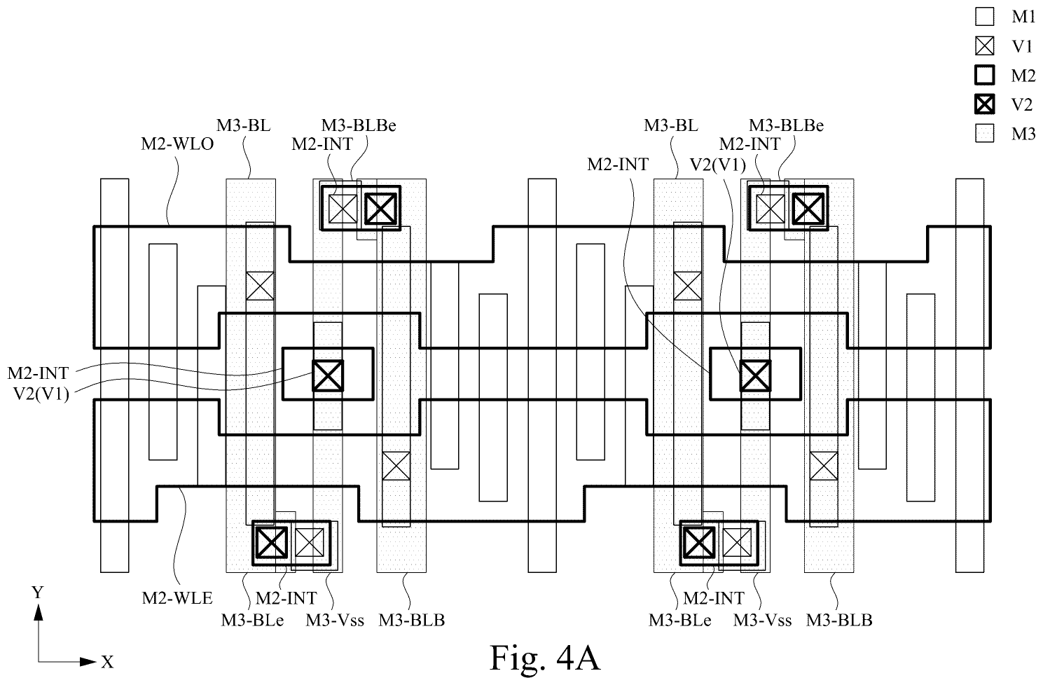

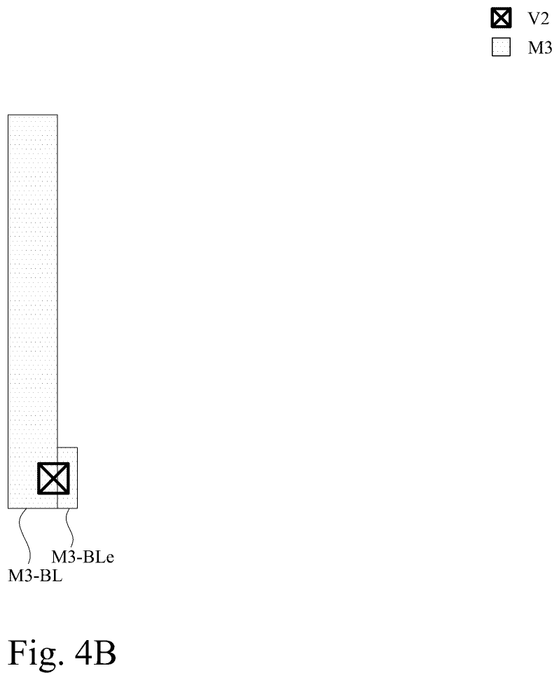

Reference is made to FIGS. 2A and 4A to illustrate the layout of the metal lines M1 and metal lines M2 and M3 above the metal lines M1, in accordance with some embodiments. The metal lines M1, M2 and M3 used as interconnect structures may be three metallization layers, with three layers of metallization interconnect via via-0 (e.g., the contact vias 244), via-1 (e.g., interconnect vias V1) and via-2 (e.g., interconnect vias V2). Other embodiments may contain more or fewer metallization layers and corresponding more or fewer number of interconnect vias. The metal lines in the metallization layer illustrated here just for an example, and the metal lines may be otherwise oriented (rotated 90 degrees or at other orientations). For illustration, the contact vias 244 (i.e., metallization interconnect via via-0) lower than the M1 level are not illustrated in FIG. 4A.

FIG. 4A illustrates a cell array layout diagram of the memory cell 10A, 10B, 10C and 10D from a first interconnection layer (e.g., metal lines M1) to a third interconnection layer (e.g., metal lines M3) of the semiconductor structure 100 of FIGS. 2A and 2B. The metal lines M2 are formed over the metal lines M1 and may be electrically connected to the metal lines M1 through the interconnect vias V1. The metal lines M3 are formed over the metal lines M2 and may be electrically connected to the metal lines M2 through the interconnect vias V2.

As illustrated in FIGS. 2A and 4A, the metal lines M2 is formed above the metal lines M1 and extend in the X-direction. The metal lines M2 includes metal lines M2-WLO, M2-WLE and M2-INT. The metal lines M2-WLO and M2-WLE extend along the X-direction, which is the longitudinal direction of the gate electrodes 220. The metal lines M2-WLO may be used to connect an odd word line to the gates of the pass-gate transistors PG-11 and PG-21 in the memory cell 10A and the gates of the corresponding pass-gate transistors in the memory cell 10C. The gate electrode 220a of the pass-gate transistors PG-11 and the gate electrode 220d of the pass-gate transistors PG-21 are electrically coupled to the metal line M1-WL in the memory cell 10A, as illustrated in FIGS. 2A and 2B, and in FIG. 4A the metal line M1-WL in the memory cell 10A is electrically coupled to the metal line M2-WLO through the underlying interconnect vias V1.

Similarly, the metal lines M2-WLE may be used to connect an even word line different from the odd word line to the gates of the pass-gate transistors PG-12 and PG-22 in the memory cell 10B and the gates of the corresponding pass-gate transistors in the memory cell 10D. The gate electrode 220a of the pass-gate transistors PG-12 and the gate electrode 220d of the pass-gate transistors PG-22 are electrically coupled to the metal line M1-WL in the memory cell 10B, as illustrated in FIGS. 2A and 2B, and in FIG. 4A the metal line M1-WL in the memory cell 10B is electrically coupled to the metal line M2-WLE through the underlying interconnect vias V1.

The metal lines M2-INT may be used as interconnection structures between the metal lines M1 and M3. As illustrate in FIGS. 2A and 4A, the metal lines M2-INT are formed over and electrically connected to the metal lines M1-Vss, M1-BL and M1-BLB through the interconnect vias V1. On regions of the metal lines M1-Vss, the interconnect vias V2 are aligned with and overlap the interconnect vias V1. On regions of the metal lines M1-BL and M1-BLB, the interconnect vias V1 may be offset from the interconnect vias V2.

In FIG. 4A, the metal lines M3 over the metal lines M2 extend in the Y-direction. In some embodiments, the metal lines M3 may include metal lines M3-Vss, M3-BL and M3-BLB. The metal lines M3-Vss may be used to connect the source/drain regions of the pull-down transistors to the ground Vss. As illustrated in FIGS. 2A and 2B, the source/drain contact 240c is the common source/drain contact of the pull-down transistors PD-11, PD-12, PD-21 and PD-22, the source/drain contact 240c is electrically coupled to the metal line M1-Vss through the contact via 244c, and in FIG. 4A the metal line M1-Vss is electrically coupled to the metal line M3-Vss through the metal line M2-INT and corresponding interconnect vias V1 and V2. In some embodiments, the interconnect vias V1 and V2 used for connecting the metal lines M1-Vss and M3-Vss are aligned with each other so that the interconnect vias V2 directly overlaps the interconnect vias V1, which is presented as V2 (V1) in FIG. 4A.

The metal lines M3-BL may be used to connect the source/drain regions of the pass-gate transistors to the bit line BL. As illustrated in FIGS. 2A and 2B, the common source/drain contact 240a of the pass-gate transistors PG-11 and PG-12 is electrically coupled to the metal line M1-BL, and in FIG. 4A the metal line M1-BL is electrically coupled to the metal line M3-BL through the metal line M2-INT and the corresponding interconnect vias V1 and V2 overlapping the underlying metal line M1-BL. In some embodiments, as illustrated in FIG. 4A, the interconnect vias V1 and V2 are offset from each other in the X-direction. In one or more embodiments of the present disclosure, the metal lines M3 further includes metal portions M3-BLe extend from a side of the metal line M3-BL along the X-direction so that the metal lines M3-BL and M3-BLe are able to overlap most of an area of the interconnect vias V2 over the underlying the metal line M1-BL.

FIG. 4B illustrates the metal line M3-BL and the metal portion M3-BLe overlapping the underlying interconnect via V2 according to one or more embodiments of the present disclosure. The metal line M3-BL extends in the Y-direction. The metal portion M3-BLe extends from a side of the metal line M3-BL in the X-direction direction. A top view area of the metal portion M2-BLe is less than a top view area of the metal line M3-BL. As illustrated in FIG. 4B, the metal line M3-BL may be regarded as a first conductive pattern over the underlying interconnect via V2 and partially overlaps the underlying interconnect via V2, and the metal line M3-BLe may be regarded as a second conductive pattern abutting the first conductive pattern of the metal line M3-BL and partially overlaps the underlying interconnect via V2. In some embodiments, a top view area of the underlying interconnect via V2 overlapped by the metal line M3-BL and the metal portion M3-BLe may be greater than about 75% of the total top view area of the underlying interconnect via V2, so that most of the underlying interconnect via V2 is overlapped by the metal line M3-BL and the metal portion M3-BLe. In some embodiments, an entirety of the top surface of the underlying interconnect via V2 is overlapped by the metal line M3-BL and the metal portion M3-BLe.

The metal lines M3-BLB may be used to connect the source/drain regions of the pass-gate transistors to the bit line BLB, wherein the bit lines BL and BLB may form a bit line pair. As illustrated in FIGS. 2A and 2B, the common source/drain contact 240f of the pass-gate transistors PG-21 and PG-22 is electrically coupled to the metal line M1-BLB, and in FIG. 4A the metal line M1-BLB is electrically coupled to the metal line M3-BLB through the metal line M2-INT and the corresponding interconnect vias V1 and V2 overlapping the underlying metal line M1-BLB. In some embodiments, as illustrated in FIG. 4A, the interconnect vias V1 and V2 are offset from each other in the X-direction. In one or more embodiments of the present disclosure, similar to the metal portions M3-BLe, the metal lines M3 further includes metal portions M3-BLBe extend from a side of the metal line M3-BLB along the X-direction so that the metal lines M3-BLB and M3-BLBe are able to overlap most of an area of the interconnect vias V2 over the underlying the metal line M1-BLB.

The metal line M3-BBL extends in the Y-direction. The metal portion M3-BLBe extends from a side of the metal line M3-BLB in the X-direction direction. A top view area of the metal portion M2-BLBe is less than a top view area of the metal line M3-BL. In some embodiments, the metal line M3-BLB may be regarded as a third conductive pattern over the underlying interconnect via V2 and partially overlaps the underlying interconnect via V2, and the metal line M3-BLBe may be regarded as a fourth conductive pattern abutting the first conductive pattern of the metal line M3-BLB and partially overlaps the underlying interconnect via V2. In some embodiments, a top view area of the underlying interconnect via V2 overlapped by the metal line M3-BLB and the metal portion M3-BLBe may be greater than about 75% of the total top view area of the underlying interconnect via V2, so that most of the underlying interconnect via V2 is overlapped by the metal line M3-BLB and the metal portion M3-BLBe. In some embodiments, an entirety of the top surface of the underlying interconnect via V2 is overlapped by the metal line M3-BLB and the metal portion M3-BLBe.

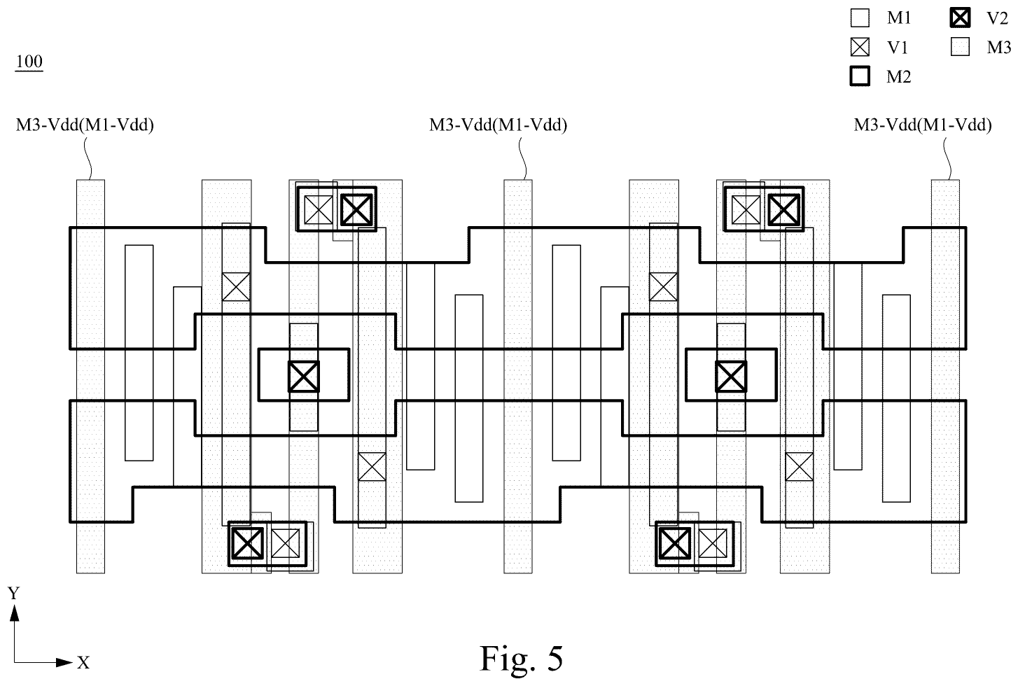

FIG. 5 illustrates a cell array layout diagram of the semiconductor structure 100 in accordance with some embodiments. A difference between the structures of FIGS. 4A and 5 may include that in FIG. 5 the metal lines M3 further include metal lines M3-Vdd overlapping the underlying metal lines M1-Vdd. In some embodiments, the metal lines M1-Vdd and M3-Vdd are aligned with each other, which is presented as M3-Vdd (M1-Vdd) in FIG. 5.

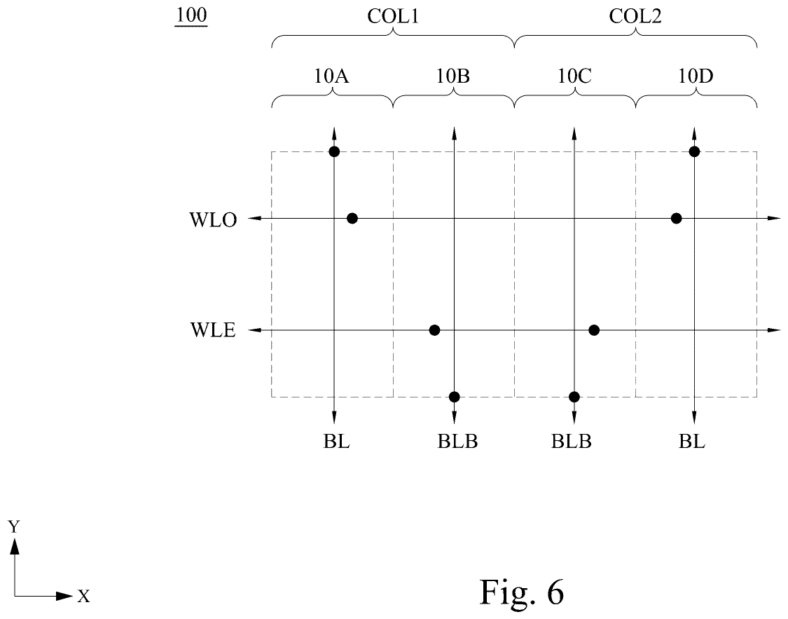

Reference is made to FIG. 6 to summarize the layout diagram as illustrated in FIGS. 2A, 2B, 4A and 4B. FIG. 6 illustrates a simplified diagram of the column COL1 in the semiconductor structure 100. In one or more embodiments of the present disclosure, a SRAM array may include plurality of grouped memory cells (e.g., memory cells 10A and 10B) in word-line routing direction (e.g., X-direction), and each grouped cell may include two adjacent cells (e.g., memory cells 10A and 10B) that placed in word-line routing direction (e.g., X-direction) and shared one bit-line pair including bit lines BL and BLB.

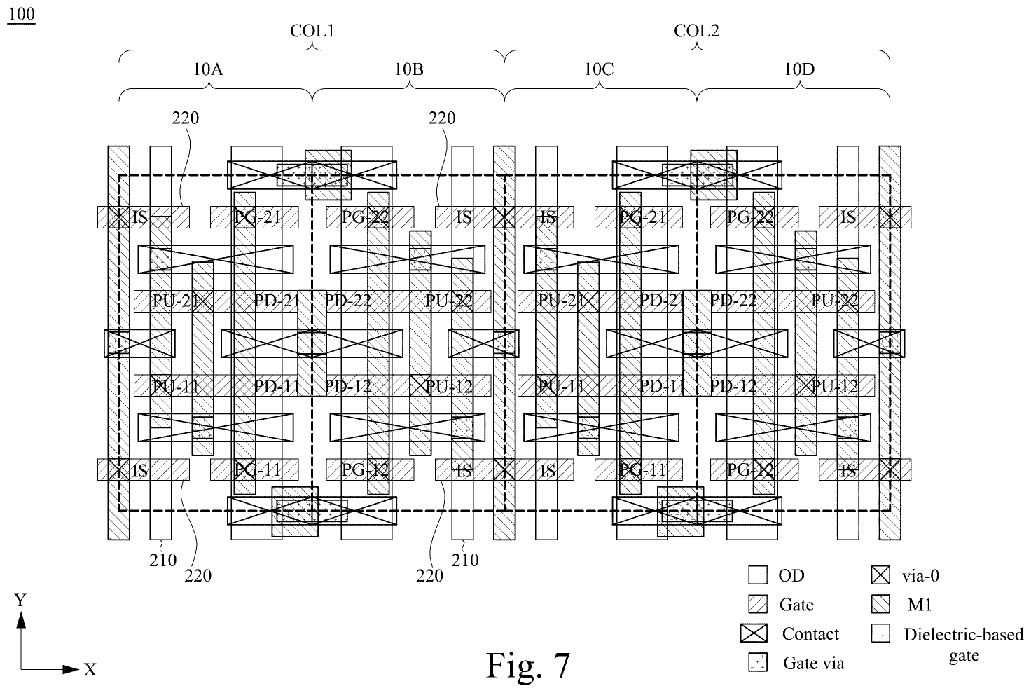

FIG. 7 illustrates a layout of a semiconductor structure 100, in accordance with some embodiments. A difference between the layouts of the semiconductor structure 100 of FIGS. 2A and 7 may include that in FIG. 7, a plurality of isolation transistors IS are provided for cell isolation. In other words, the dielectric-based gates 225a and 225b are replaced by the isolation transistors IS. As shown in FIG. 7, the gate electrodes 220 further includes gate electrodes 220 extending in the X-direction. The gate electrodes 220 in the X-direction overlaps the underlying semiconductor sheets 210a to form isolation transistors IS on the boundary of the memory cells 10A, 10B, 10C and 10D, and the gate electrodes 220 of the isolation transistors IS are electrically coupled to the metal lines M1-Vdd through the gate vias 250 overlapping the underlying gate electrodes 220.

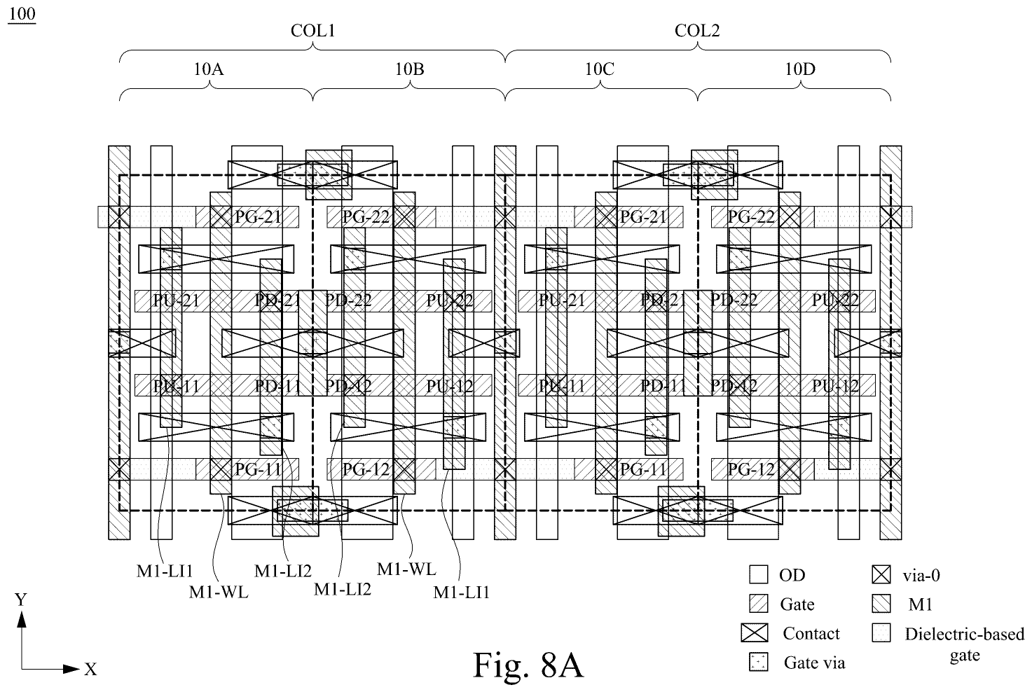

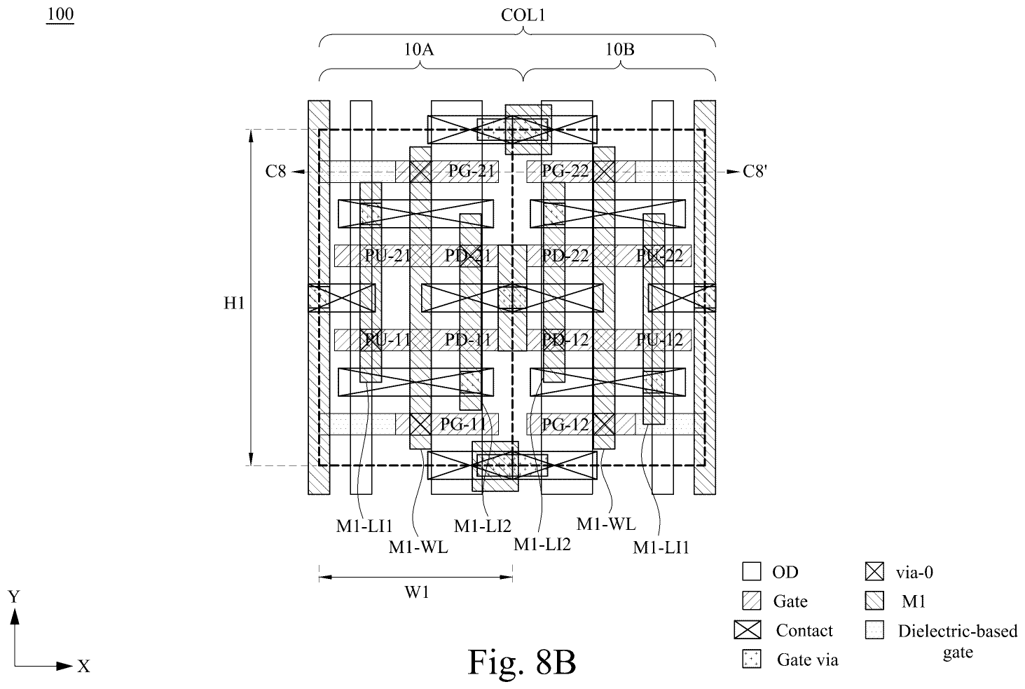

FIG. 8A illustrates a layout of a semiconductor structure 100, in accordance with some embodiments. FIG. 8B illustrates a column COL1 of the layout of FIG. 8A, in accordance with some embodiments. A difference between the layouts of the semiconductor structure 100 of FIGS. 2A and 8A may include that longitudinal ends of the dielectric-based gates 225a and 225b abut longitudinal ends of the adjacent gate electrodes 220 and each metal line M1-WL moves between the metal lines M1-LI1 and M1-LI2 in each of the memory cells 10A, 10B, 10C and 10D. The dielectric-based gates 225a and 225b directly adjacent the gate electrodes 220 can facilitate Vg-to-gate connection margin improvement.

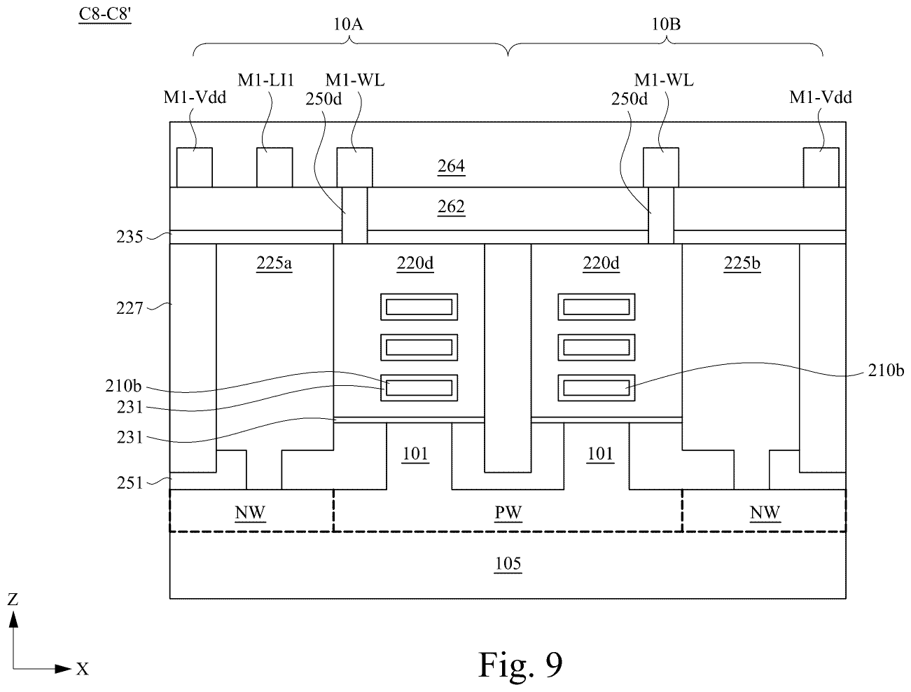

FIG. 9 illustrates a cross-sectional view obtained from a reference cross-sections C8-C8′ in FIG. 8B. FIG. 9 illustrates the cross-section view obtained from the reference cross-section C8-C8′, which is parallel to X-direction and across the abutting dielectric-based gate 225a, the pass-gate transistor PG-21 in the memory cell 10A, the pass-gate transistor PG-22 in the memory cell 10B and the abutting dielectric-base gate 225b.

Reference is made to FIGS. 8B and 9. The semiconductor sheets 210b over the p-type well regions NW in the memory cell 10A is wrapped by the gate electrode 220d with the gate dielectric layer 231 to form the pass-gate transistor PG-21. The semiconductor sheets 210b over the p-type well regions NW in the memory cell 10B is wrapped by the gate electrode 220d with the gate dielectric layer 231 to form the pass-gate transistor PG-22. As illustrated in FIG. 9, all of the semiconductor sheets 210a over the n-type well regions NW in the memory cell 10A is removed to form the dielectric-based gate 225a abutting the gate electrode 220d in the memory cell 10A, and the semiconductor sheets 210a over the n-type well regions NW in the memory cell 10B is removed to form the dielectric-based gate 225b abutting the gate electrode 220d in the memory cell 10B. The gate electrodes 220d are electrically coupled to the metal lines M1-W1 by the gate vias 250d passing through the ILD layer 262 and the hard mask layer 235.

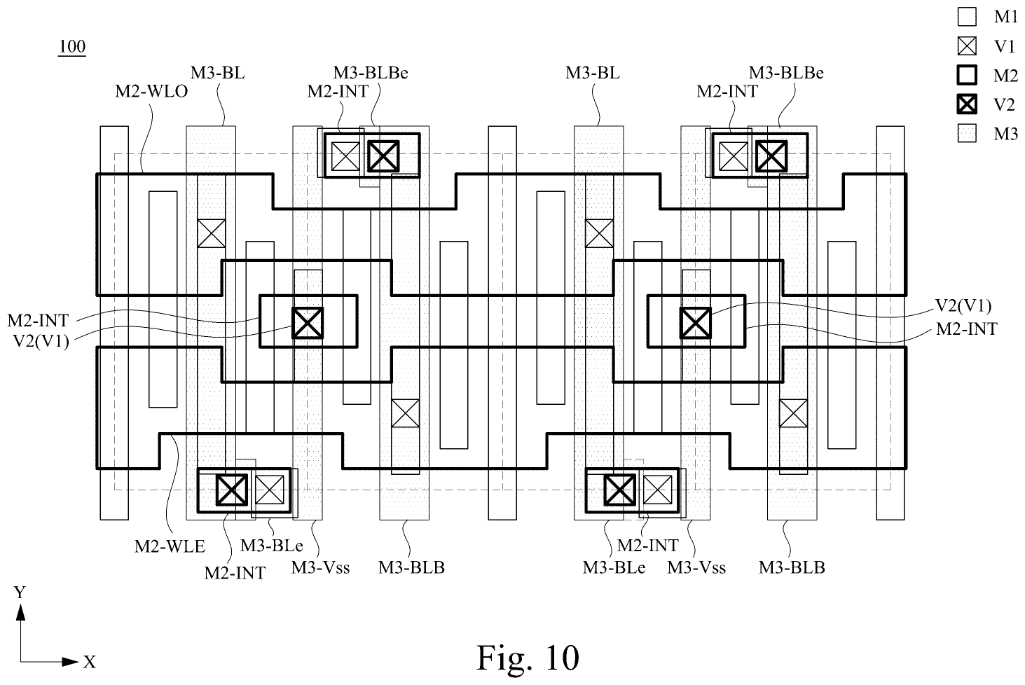

FIG. 10 illustrate a cell array layout diagram of the metal lines M1 and metal lines M2 and M3 above the metal lines M1 as illustrated in FIG. 8A, in accordance with some embodiments. A difference between the structures of FIGS. 4A and 10 may include that the interconnect vias V1 are moved to overlaps the underlying metal lines M1-WL between the metal lines M1-LI1 and M1-LI2.

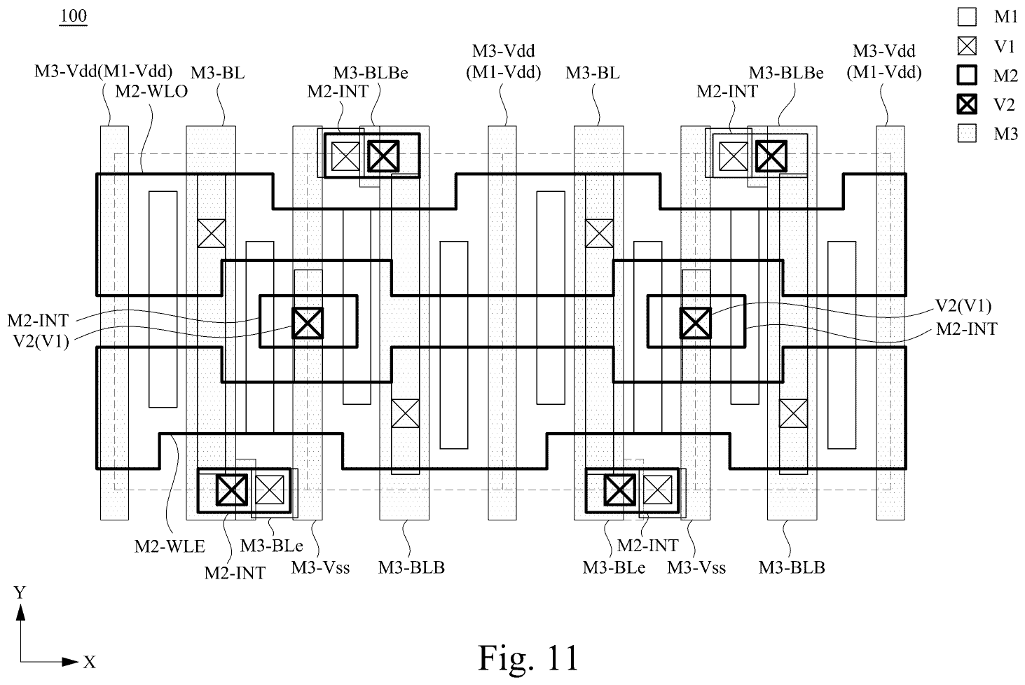

FIG. 11 illustrates a cell array layout diagram of the semiconductor structure 100 in accordance with some embodiments. A difference between the structures of FIGS. 10 and 11 may include that in FIG. 11 the metal lines M3 further include metal lines M3-Vdd overlapping the underlying metal lines M1-Vdd. In some embodiments, the metal lines M1-Vdd and M3-Vdd are aligned with each other, which is presented as M3-Vdd (M1-Vdd) in FIG. 11.

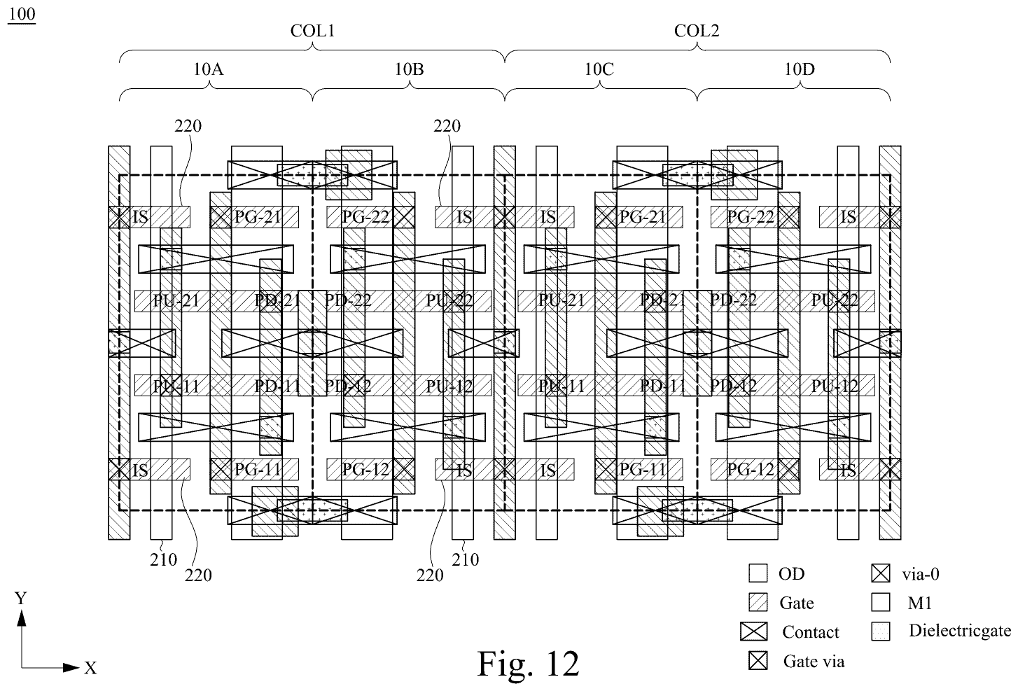

FIG. 12 illustrates a layout of a semiconductor structure 100, in accordance with some embodiments. A difference between the layouts of the semiconductor structure 100 of FIGS. 8A and 12 may include that in FIG. 12, a plurality of isolation transistors IS are provided for cell isolation. In other words, the dielectric-based gates 225a and 225b are replaced by the isolation transistors IS. As shown in FIG. 12, the gate electrodes 220 further includes gate electrodes 220 extending in the X-direction. The gate electrodes 220 in the X-direction overlaps the underlying semiconductor sheets 210a to form isolation transistors IS on the boundary of the memory cells 10A, 10B, 10C and 10D, and the gate electrodes 220 of the isolation transistors IS are electrically coupled to the metal lines M1-Vdd through the gate vias 250 overlapping the underlying gate electrodes 220.

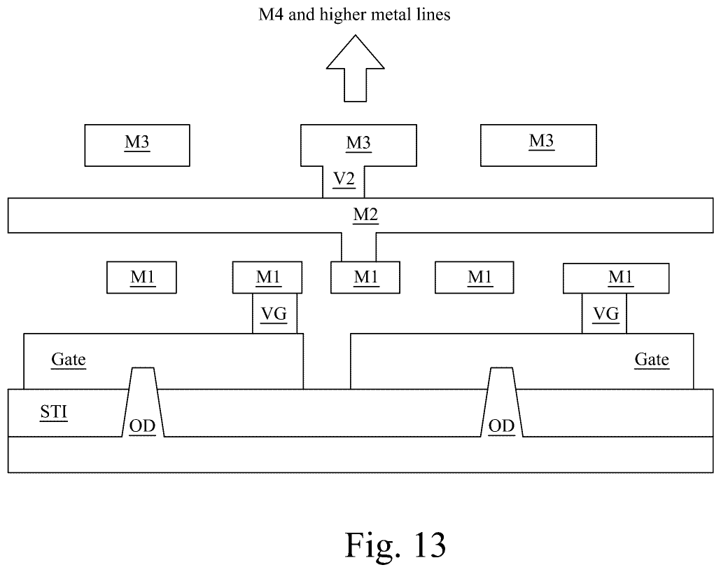

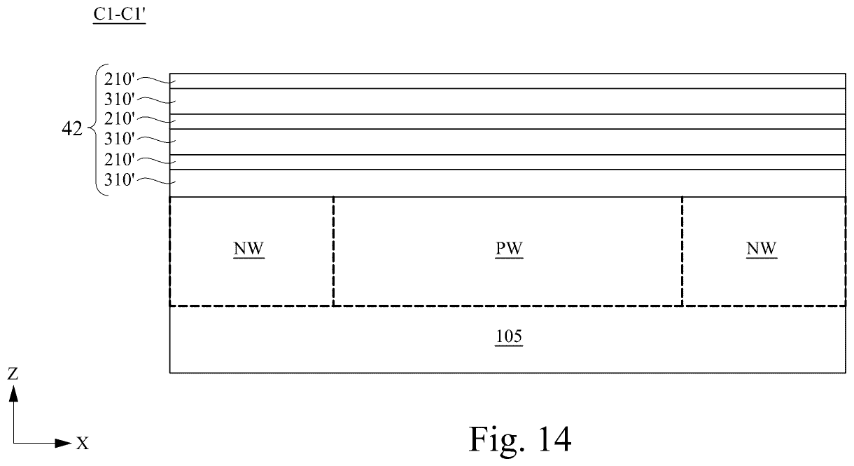

Reference is made to FIG. 13. FIG. 13 illustrates a schematic view of a semiconductor structure in accordance with some embodiments of the present disclosure. It is noted that FIG. 13 is schematically illustrated to show various levels of interconnect structure and transistors, and may not reflect the actual cross-sectional view of SRAM cell. The interconnect structure includes a contact level, an OD (wherein the term “OD” represents “active region”) level, via levels, such as gate via level, vial level, Via2 level, and Via3 level, and metal-layer levels, such as M1 level, M2 level and M3 level. Each of the illustrated levels includes one or more dielectric layers and the conductive features formed therein. The conductive features that are at the same level may have top surfaces substantially level to each other, bottom surfaces substantially level to each other, and may be formed simultaneously. The contact level may include gate vias (also referred to as contact plugs) for connecting gate electrodes of transistors (such as the illustrated exemplary transistors) to an overlying level such as the gate via level.

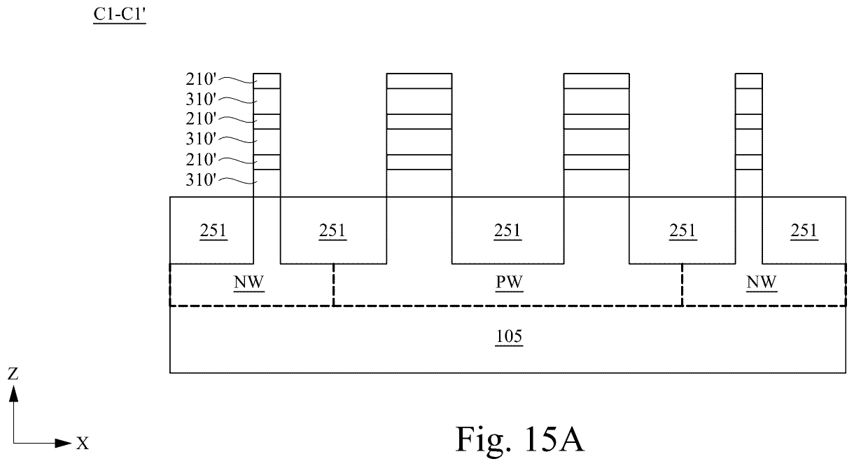

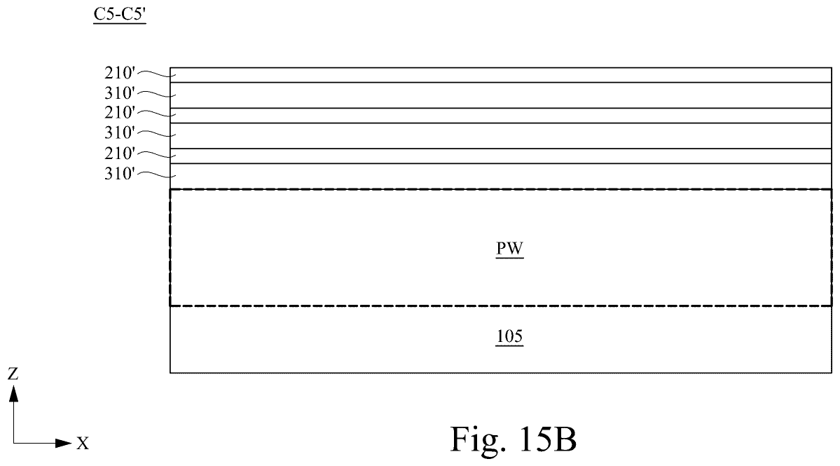

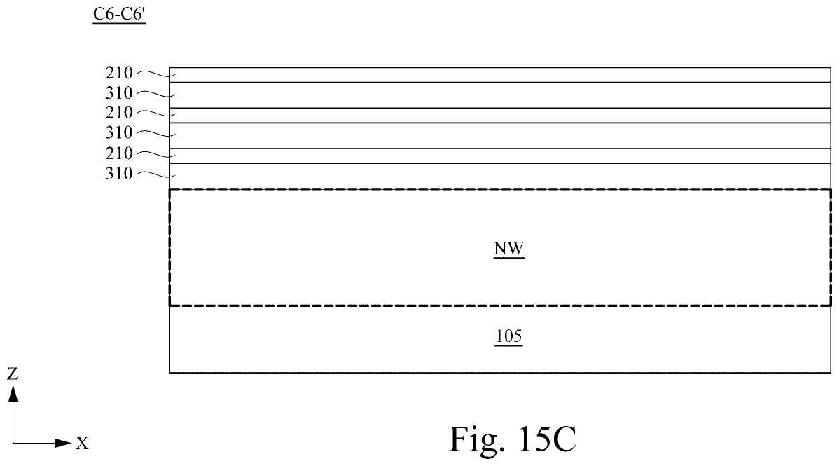

Reference is made to FIGS. 14 through 19C. FIGS. 14 through 19C illustrate schematic views of intermediate stages in the formation of a semiconductor structure in accordance with some embodiments. FIGS. 14, 15A and 19A illustrate cross-sectional views of intermediate stages obtained from the reference cross-section C1-C1′ of the top view as illustrated in FIG. 2B in the formation of the semiconductor structure in accordance with some embodiments. FIGS. 15B, 16A, 17A, 18A and 19B illustrate cross-sectional views of intermediate stages obtained from the reference cross-section C5-C5′ of the top view as illustrated in FIG. 2B in the formation of the semiconductor structure in accordance with some embodiments. FIGS. 15C, 16B, 17B, 18B and 19C illustrate cross-sectional views of intermediate stages obtained from the reference cross-section C6-C6′ of the top view as illustrated in FIG. 2B in the formation of the semiconductor structure in accordance with some embodiments.

As with the other method embodiments and exemplary devices discussed herein, it is understood that parts of the semiconductor structure 100 may be fabricated by a complementary metal-oxide-semiconductor CMOS technology process flow, and thus some processes are only briefly described herein. Further, the exemplary integrated circuit structure 100 may include various other devices and features, such as other types of devices such as additional transistors, bipolar junction transistors, resistors, capacitors, inductors, diodes, fuses, and/or other logic circuits, etc., but is simplified for a better understanding of the concepts of the present disclosure. In some embodiments, the exemplary semiconductor structure 100 includes a plurality of semiconductor devices (e.g., transistors), including PFETs, NFETs, etc., which may be interconnected. It is understood that additional operations can be provided before, during, and after the processes shown by FIGS. 14 through 19C, and some of the operations described below can be replaced or eliminated, for additional embodiments of the method. The order of the operations/processes may be interchangeable.

Reference is made to FIG. 14. A substrate 105 is provided for forming nano-FETs. The substrate 105 may be a semiconductor substrate, such as a bulk semiconductor, a semiconductor-on-insulator (SOI) substrate, or the like, which may be doped (e.g., with a p-type or an n-type impurity) or undoped. The substrate 105 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the substrate 105 may be a material, such as a III-V compound semiconductor, a II-VI compound semiconductor, or the like. In some embodiments, the semiconductor material of the substrate 105 may include silicon; germanium; a compound semiconductor including silicon carbide, gallium arsenide, gallium stannum, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

By way of example and not limitation, the substrate 105 may be lightly doped with a p-type or an n-type impurity to form n-type well regions NW and p-type well region PW having an opposite conductivity type to the n-type well regions NW. An anti-punch-through (APT) implantation may be performed on an upper portion of the substrate 105 to form an APT region. During the APT implantation, impurities may be implanted in the substrate 105. The impurities may have a conductivity type opposite from a conductivity type of source/drain regions that will be subsequently formed in each of the n-type region and the p-type region. The APT region may extend under the source/drain regions in the nano-FETs. The APT region may be used to reduce the leakage from the source/drain regions to the substrate 105. In some embodiments, the doping concentration in the APT region may be in the range of about 10¹⁸ cm⁻³ to about 10¹⁹ cm⁻³. In some embodiments, the p-type well region PW can have n-type devices, such as NMOS transistors, formed thereon, and the n-type well region NW can have p-type devices, such as PMOS transistors, formed thereon.

As illustrated in FIG. 14, a multi-layer stack 42 is formed over the substrate 105. The multi-layer stack 42 can include alternating first semiconductor layers 310′ and second semiconductor layers 210′. The first semiconductor layers 310′ formed of a first semiconductor material, and the second semiconductor layers 210′ are formed of a second semiconductor material different than the first semiconductor material. The semiconductor materials may each be selected from the candidate semiconductor materials of the substrate 105. In some embodiments, the multi-layer stack 42 includes two layers of each of the first semiconductor layers 310 and the second semiconductor layers 210′. It should be appreciated that the multi-layer stack 42 may include any number of the first semiconductor layers 310′ and the second semiconductor layers 210′.

In some embodiments, and as will be subsequently described in greater detail, the first semiconductor layers 310′ will be removed and the second semiconductor layers 210′ will patterned to form channel layers for the nano-FETs. The first semiconductor layers 310′ can be sacrificial layers (or dummy layers), which will be removed in subsequent processing to expose the top surfaces and the bottom surfaces of the second semiconductor layers 210′. The first semiconductor material of the first semiconductor layers 310′ is a material that has a high etching selectivity from the etching of the second semiconductor layers 210′, such as silicon germanium. The second semiconductor material of the second semiconductor layers 210′ is a material suitable for both n-type and p-type devices, such as silicon.

In some embodiments, the first semiconductor material of the first semiconductor layers 310′ may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 210′ may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers in the multi-layer stack 42 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 42 may have a thickness in a range from about 70 to 120 nm, such as about 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers 210′) may be formed to be thinner than other layers (e.g., the first semiconductor layers 310′).

Reference is made to FIGS. 15A-15C. Trenches can be patterned in the substrate 105 and the multi-layer stack 42 to form fin strips 101, semiconductor sheets 310, and semiconductor sheets 210. The semiconductor sheets 210 may be used as channel layers 210. The semiconductor sheets 310 and the channel layers 210 include the remaining portions of the first semiconductor layers 310′ and the second semiconductor layers 210′, respectively. The trenches may be patterned by any acceptable etch process, such as a reactive ion etch (RIE), neutral beam etch (NBE), the like, or a combination thereof. The etching may be anisotropic. The fin strips 101, the semiconductor sheets 310, and the channel layers 210 may be patterned by any suitable method. For example, the fin strips 101, the semiconductor sheets 310, and the channel layers 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

The STI structures 251 can be formed over the substrate 105 and between adjacent fin strips 101. The STI structures 251 are disposed around at least a portion of the fin strips 101 such that at least a portion of the semiconductor sheet 310 and the channel layer 210 protrude from between adjacent STI structures 251. In some embodiments, the top surfaces of the STI structures 251 are coplanar (within process variations) with the top surfaces of the fin strips 101. The STI structures 251 may be formed by any suitable method. For example, an insulation material can be formed over the substrate 105 and the semiconductor sheets 310 and the channel layers 210, and between adjacent fin strips 101. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In some embodiments, the insulation material is formed such that excess insulation material covers the semiconductor sheets 310 and the channel layers 210. Although the STI structures 251 are each illustrated as a single layer, some embodiments may utilize multiple layers. For example, in some embodiments a liner (not separately illustrated) may first be formed along surfaces of the substrate 105, the fin strips 101, the semiconductor sheets 310, and the channel layers 210. Thereafter, a fill material, such as those previously described may be formed over the liner.

A removal process is then applied to the insulation material to remove excess insulation material over the semiconductor sheets 310 and the channel layers 210. In some embodiments, a planarization process such as a chemical mechanical polish (CMP), an etch-back process, combinations thereof, or the like may be utilized. In embodiments in which a mask remains on the semiconductor sheets 310 and the channel layers 210, the planarization process may expose the mask or remove the mask. After the planarization process, the top surfaces of the insulation material and the mask (if present) or the semiconductor sheet 310/the channel layer 210 are coplanar (within process variations). Accordingly, the top surfaces of the mask (if present) or the semiconductor sheet 310/channel layer 210 can be exposed through the insulation material. In some embodiments, no mask remains on the semiconductor sheets 310 and the channel layers 210. The insulation material is then recessed to form the STI structures 251. The insulation material is recessed, such as in a range from about 30 nm to about 80 nm, such that at least a portion of the semiconductor sheets 310 and the channel layers 210 can protrude from between adjacent portions of the insulation material. Further, the top surfaces of the STI structures 251 may have a flat surface as illustrated, a convex surface, a concave surface (such as dishing), or a combination thereof. The insulation material may be recessed using any acceptable etching process, such as one that is selective to the material of the insulation material (e.g., selectively etches the insulation material of the STI structures 251 at a faster rate than the materials of the fin strips 101 and the semiconductor sheets 310 and the channel layers 210). For example, an oxide removal may be performed using dilute hydrofluoric (dHF) acid.

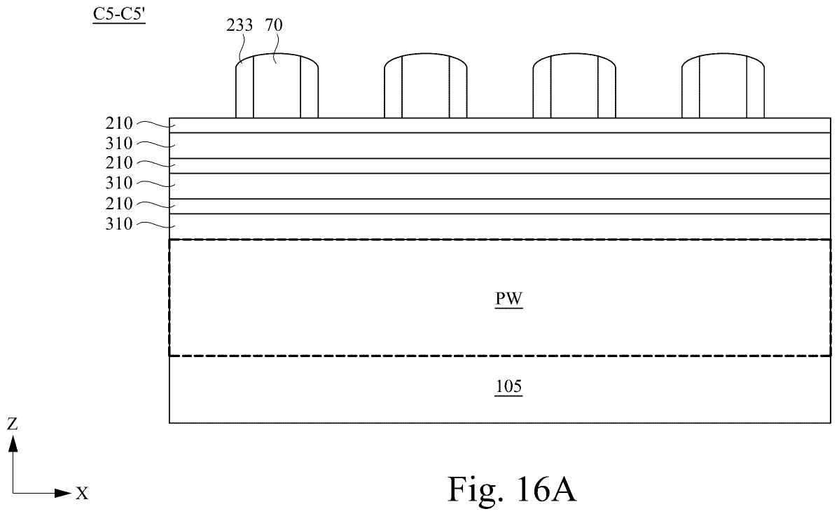

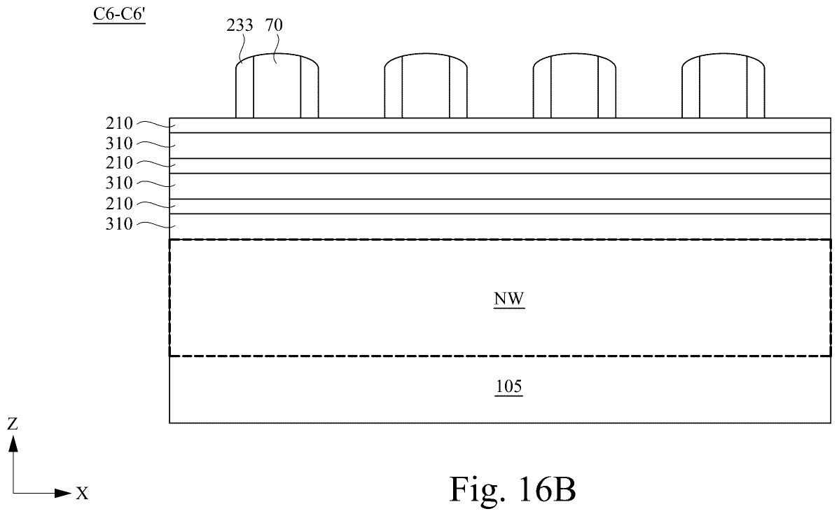

Reference is made to FIGS. 16A and 16B. A plurality of dummy gate structures 70 is formed on the fin strips 101, the semiconductor sheets 310, and the channel layers 210. In some embodiments, forming the dummy gate structures 70 may include a dummy dielectric layer, a dummy gate layer, and a mask layer are sequentially formed on the fin strips 101, the semiconductor sheets 310, and the channel layers 210.

In some embodiments, the dummy dielectric layer of the dummy gate structures 70 may be formed of a dielectric material such as silicon oxide, silicon nitride, a combination thereof, or the like, which may be deposited or thermally grown according to acceptable techniques.

Subsequently, a dummy gate layer of the dummy gate structures 70 is formed over the dummy dielectric layer. Subsequently, a mask layer is formed over the dummy gate layer. The dummy gate layer of the dummy gate structures 70 may be deposited over the dummy dielectric layer and then planarized, such as by a CMP. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer.

The mask layer of the dummy gate structures 70 may be deposited over the dummy gate layer. The mask layer may be formed of a dielectric material such as silicon nitride, silicon oxynitride, or the like. The mask layer is patterned using acceptable photolithography and etching techniques to form masks. The pattern of the masks is then transferred to the dummy gate layer and the dummy dielectric layer by any acceptable etching technique to form dummy gates. The pattern of the masks may optionally be further transferred to the dummy dielectric layer by any acceptable etching technique to form dummy dielectrics.

As illustrated in FIGS. 16A and 16B, the dummy gate structures 70 cover portions of the semiconductor sheets 310 and the channel layers 210 that will be exposed in subsequent processing to form active regions. The dummy gates may also have lengthwise directions substantially perpendicular (within process variations) to the lengthwise directions of the fin strips 101. The masks can optionally be removed after patterning, such as by any acceptable etching technique.

The layers 233 serving as gate spacers can be formed over the semiconductor sheets 310 and the channel layers 210 and on exposed sidewalls of the dummy gate structure. In some embodiments, the layer 233 can be interchangeably referred to top spacers or upper gate spacers. In some embodiments, the layer 233 may include multiple dielectric material and selected from a group consist of SiO₂, Si₃N₄, carbon doped oxide, nitrogen doped oxide, porous oxide, air gap, or combinations thereof. The layer 233 may be formed by conformally depositing one or more dielectric material(s) and subsequently etching the dielectric material(s). Acceptable dielectric materials may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gate structure 70 (thus forming the layer 233).

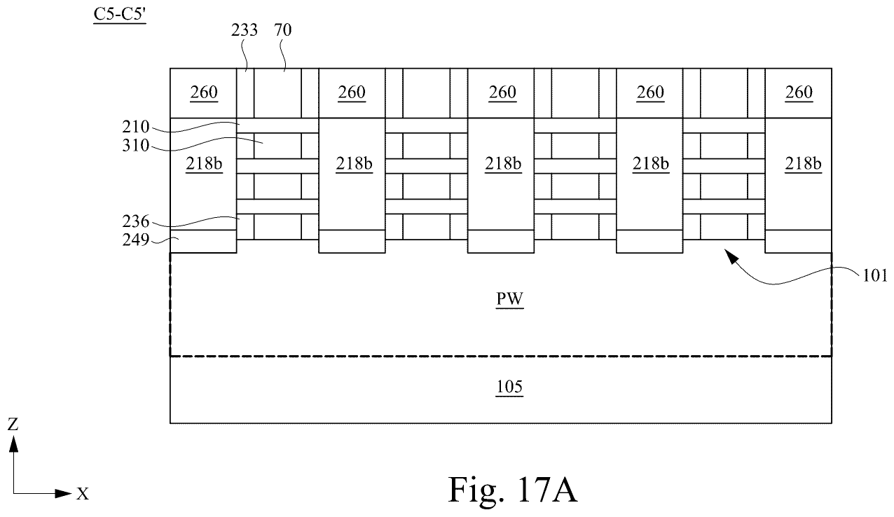

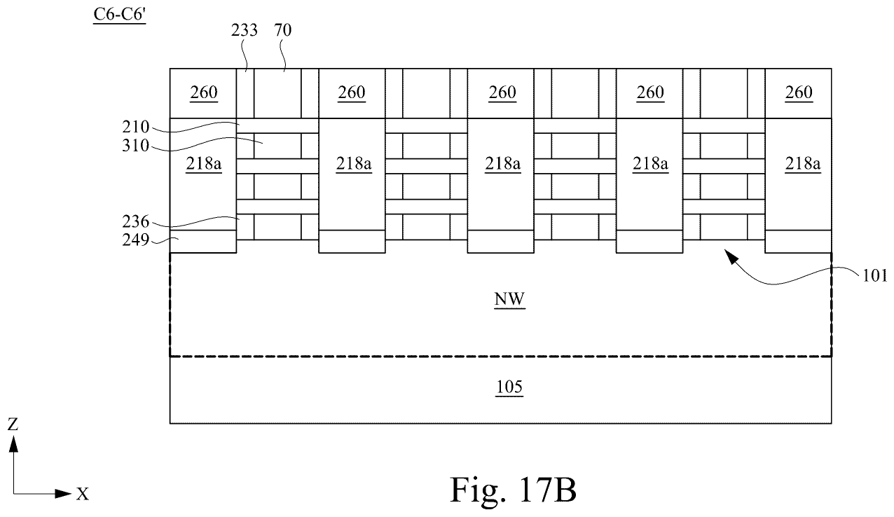

Reference is made to FIGS. 17A and 17B. Source/drain recesses can be formed in the semiconductor sheets 310 and the channel layers 210. In some embodiments, the source/drain recesses extend through the semiconductor sheets 310 and the channel layers 210 and into the fin strips 101. In some embodiments, the fin strips 101 may be etched such that bottom surfaces of the source/drain recesses 94 are disposed below the top surfaces of the STI structures 251. The source/drain recesses may be formed by etching the semiconductor sheets 310 and the channel layers 210 using an anisotropic etching processes, such as a RIE, a NBE, or the like. The layers 233 and the dummy gate structures 70 act as mask portions of the fin strips 101, the semiconductor sheets 310, and the channel layers 210 during the etching processes used to form the source/drain recesses. A single etch process may be used to etch each of the semiconductor sheets 310 and the channel layers 210, or multiple etch processes may be used to etch the semiconductor sheets 310 and the channel layers 210. Timed etch processes may be used to stop the etching of the source/drain recesses after the source/drain recesses reach a desired depth.

Subsequently, inner spacers 236 are formed on sidewalls of the remaining portions of the semiconductor sheets 310, e.g., those sidewalls exposed by the source/drain recesses. As will be subsequently described in greater detail, source/drain regions will be subsequently formed in the source/drain recesses, and the semiconductor sheets 310 will be subsequently replaced with corresponding gate structures. The inner spacers 236 act as isolation features between the subsequently formed source/drain regions and the subsequently formed gate structures. Further, the inner spacers 236 may be used to substantially prevent damage to the subsequently formed source/drain regions by subsequent etching processes, such as etching processes used to subsequently remove the semiconductor sheets 310.

As an example to form the inner spacers 236, the source/drain recesses can be laterally expanded. Specifically, portions of the sidewalls of the semiconductor sheets 310 exposed by the source/drain recesses 94 may be recessed. Although sidewalls of the semiconductor sheets 310 are illustrated as being straight, the sidewalls may be concave or convex. The sidewalls may be recessed by any acceptable etching process, such as one that is selective to the material of the semiconductor sheets 310 (e.g., selectively etches the material of the semiconductor sheets 310 at a faster rate than the material of the channel layers 210). The etching may be isotropic. For example, when the channel layers 210 are formed of silicon and the semiconductor sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the semiconductor sheets 310.

The inner spacers 236 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236 may have a higher K (dielectric constant) value than the layer 233. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236 are illustrated as being flush with respect to the sidewalls of the layer 233, the outer sidewalls of the inner spacers 236 may extend beyond or be recessed from the sidewalls of the layer 233. In other words, the inner spacers 236 may partially fill, completely fill, or overfill the sidewall recesses. Moreover, although the sidewalls of the inner spacers 236 are illustrated as being straight, the sidewalls of the inner spacers 236 may be concave or convex.

Eepitaxial source/drain regions 218 can be formed in the source/drain recesses, such that each dummy gate structure 70 (and corresponding channel layers) is disposed between respective adjacent pairs of the epitaxial source/drain regions 218. In some embodiments, the gate spacers 233 and the inner spacers 236 are used to separate the epitaxial source/drain regions 218 from, respectively, the dummy gate structures 70 and the semiconductor sheets 310 by an appropriate lateral distance so that the epitaxial source/drain regions 218 do not short out with subsequently formed gates of the resulting nano-FETs.

As illustrated in FIGS. 17A and 17B, the source/drain regions 218 may include p-type source/drain regions 218a over the n-type well region NW and n-type source/drain regions 218b over the p-type well region PW. In some embodiments, the n-type source/drain regions 218b may include SiP, SiC, SiPC, SiAs, Si, or a combination thereof. In some embodiments, the n-type source/drain regions 218b may have a phosphorus concentration within a range from about 2E19/cm³ to about 3E21/cm³. In some embodiments, the p-type source/drain regions 218a may include boron, BF₂, SiGe, or a combination thereof. In some embodiments, the p-type source/drain regions 218a may have a boron concentration within a range from about 1E19/cm³ to about 6E20/cm³. In some embodiments, the p-type source/drain regions 218a may have a Ge atomic percentage within a range of about 36% to about 85%. In some embodiments, 218a having the p-type dopant may include a carbon-containing material.

In some embodiments, as illustrated in FIGS. 17A and 17B, a plurality of dielectric layers 249 may be formed om the source/drain recesses before the source/drain regions 218 is formed. In some embodiments, the dielectric layer 249 can be interchangeably referred to a dielectric barrier layer or a leakage barrier for reducing leakage current. In some embodiments, the dielectric layer 249 can be made of a different material than the inner spacer 236. In some embodiments, the dielectric layer 249 can be made of a same material as the inner spacer 236. In some embodiments, the dielectric layer 249 can be formed during a same process as forming the inner spacer 236, in which the material to form the inner spacer 236 can be remained at the bottom 94b of the recess 94 to act as the dielectric layer 249. In some embodiments, the dielectric layer 249 is made of an oxide-containing material (e.g., SiO₂), a nitrogen-containing material (e.g., SiON, SiN, Si₃N₄), a carbon-containing material (e.g., SiOC, SIOCN), the like, or combinations thereof. In some embodiments, the dielectric layer 249 may be made of a material having a dielectric constant greater than about 7.9 (e.g., high dielectric constant (high-k) material). For example, the dielectric layer 249 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

An inter-layer dielectric (ILD) layer 260 can be deposited over the epitaxial source/drain regions 218, the gate spacers 233, and the dummy gate structure 70. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. In some embodiments, the ILD layers 260 and 262 may be made of an oxide, nitride, the like, or combinations thereof. Other insulation materials formed by any acceptable process may be used. In some embodiments, a contact etch stop layer (CESL) is formed between the ILD layer 260 and the epitaxial source/drain regions 218, the gate spacers 233, and the dummy gate structure 70. The CESL may be formed of a dielectric material, such as silicon nitride, silicon oxide, silicon oxynitride, or the like, having a high etching selectivity from the etching of the ILD 260. The CESL may be formed by an any suitable method, such as CVD, ALD, or the like.

Subsequently, a removal process is performed to level the top surfaces of the ILD layer 260 with the top surfaces of the dummy gate structure 70. In some embodiments, a planarization process such as a chemical mechanical polish (CMP), an etch-back process, combinations thereof, or the like may be utilized. After the planarization process, the top surfaces of the gate spacers 233, the ILD layer 260, the CESL, and the dummy gate structure 70 are coplanar (within process variations). Accordingly, the top surfaces of the dummy gate structure 70 can be exposed through the ILD layer 260. In some embodiments, the dummy gate structures 70 remain, and the planarization process levels the top surface of the ILD layer 260 with the top surfaces of the dummy gate structures 70.

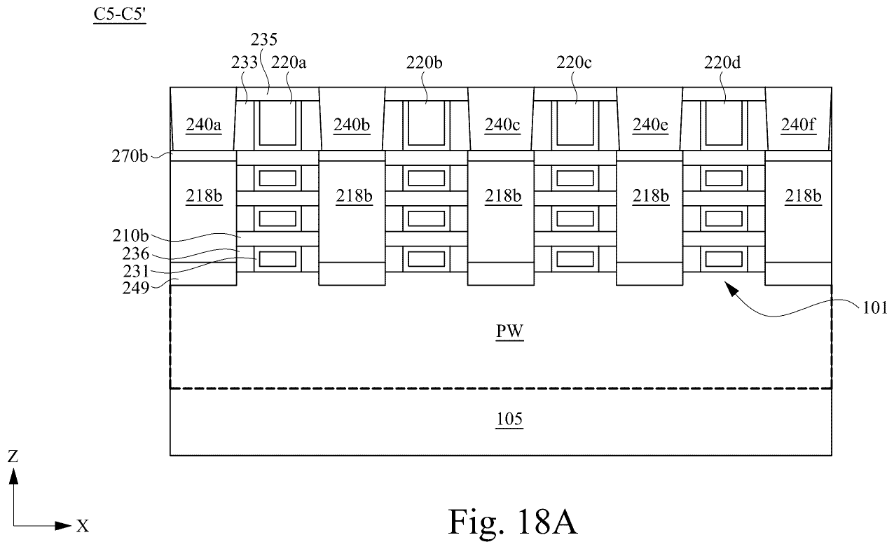

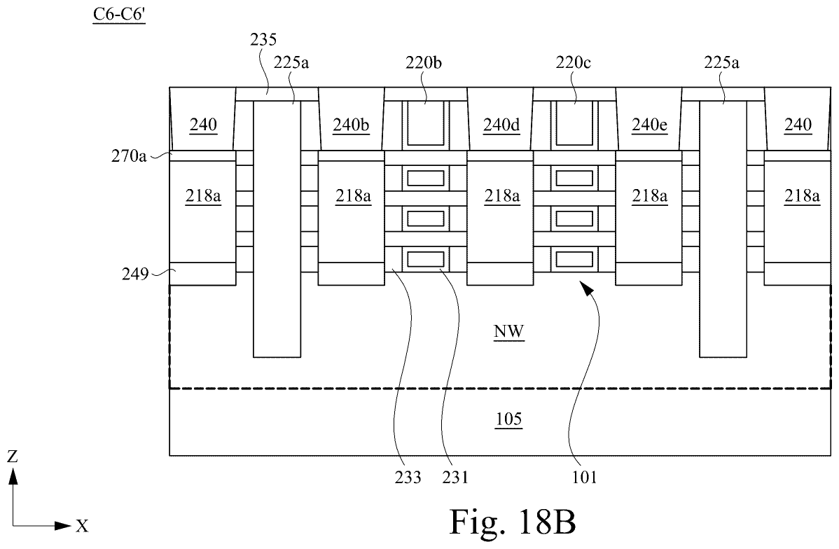

Reference is made to FIGS. 18A and 18B. The dummy gate structures 70 are removed in an etching process, so that recesses 126 are formed. In some embodiments, the dummy gate structures 70 are removed by an anisotropic dry etch process. For example, the etching process may include a dry etch process using reaction gas(es) that selectively etch the dummy gate structures 70 at a faster rate than the ILD layer 260 and the gate spacers 233. Each recess can expose and/or overlies portions of the channel layers 210 disposed between adjacent pairs of the epitaxial source/drain regions 218.

The remaining portions of the semiconductor sheets 310 are then removed to expand the recesses, such that openings are formed in regions between the channel layers 210. The remaining portions of the semiconductor sheets 310 can be removed by any acceptable etching process that selectively etches the material of the semiconductor sheets 310 at a faster rate than the material of the channel layers 210. The etching may be isotropic. For example, when the semiconductor sheets 310 are formed of silicon germanium and the channel layers 210 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the channel layers 210. In some embodiments, the removing of the remaining portions of the semiconductor sheets 310 can be interchangeably referred to as a channel releasing process. The channel layers 210 can be interchangeably referred to as a vertically stacked multiple channels (sheets) and may have a vertically sheet pitch within a range of from about 10 nm to about 30 nm. In some embodiments, the channel layers 210 may have a thickness within a range from about 4 nm to about 10 nm. In some embodiments, the vertically sheet pitch of the between adjacent two of the channel layers 210 may be within a range from about 6 to about 20 nm.

Gate dielectric layers 231 are formed in the recesses exposing the channel layers 210. Gate electrodes 220 are formed over the gate dielectric layers 231. The gate electrodes may include gate electrodes 220a, 220b, 220c and 220d. The gate dielectric layers 231 and the gate electrodes 220 form replacement gate structures wrap around the channel layers 210, and each wrap around all (e.g., four) sides of the second channel layer 210. Specifically, the gate dielectric layer 231 is disposed on the sidewalls and/or the top surfaces of the fin strips 101; on the top surfaces, the sidewalls, and the bottom surfaces of the channel layers 210; and on the sidewalls of the gate spacers 233. Subsequently, the gate electrodes 220 is formed over the gate dielectric layer 231.

In some embodiments, the gate dielectric layers 231 can be formed over top surfaces of the fin strip 101 and along top surfaces, sidewalls, and bottom surfaces of the channel regions 210. The gate electrodes 220 are formed over the gate dielectric layer 231. In some embodiments, the gate electrodes 220 may be made of conductive material, such as aluminum (Al), copper (Cu), tungsten (W), titanium (Ti), tantalum (Ta), or other applicable materials. In some embodiments, the gate electrode 220 may include multiple material structure selected from a group consisting of poly gate/SiON structure, metals/high-K dielectric structure, Al/refractory metals/high-K dielectric structure, silicide/high-K dielectric structure, or combination. In some embodiments, the gate electrodes 220 may include one or more work-function layers (not shown). In some embodiments, the work function layer can be made of metal material, and the metal material may include N-work-function metal or P-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal may include titanium nitride (TiN), tungsten nitride (WN), tantalum nitride (TaN), ruthenium (Ru) or a combination thereof. In some embodiments, the gate electrode 220 is formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

In some embodiments, the gate dielectric layers 231 can be made of silicon oxide (SiOₓ), silicon nitride (SiₓN_{y}), silicon oxynitride (SiON), dielectric material(s) with high dielectric constant (high-k), or a combination thereof. The high dielectric constant (high-k) material may be hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. In some embodiments, the gate dielectric layer 231 includes Lanthanum (La) dopant. In some embodiments, the gate dielectric layer 231 can be deposited by a plasma enhanced chemical vapor deposition (PECVD) process or by a spin coating process.

The dielectric region 227 can be formed as a gate-cut structure for the gate structure. In some embodiments, the dielectric regions 227 can be formed by a cut metal gate (CMG) process. Specifically, portions of the gate electrodes 220 and the gate dielectric layers 231 are removed to reappear portions of the gate trenches with the gate spacers 215 as their sidewalls. The portions of the gate electrodes 220 and the gate dielectric layer 231 may be removed by dry etching, wet etching, or a combination of dry and wet etching. For example, a wet etching process may include exposure to a hydroxide containing solution (e.g., ammonium hydroxide), deionized water, and/or other suitable etchant solutions. Subsequently, a dielectric material is deposited into the gate trenches, followed by a planarization process to remove excess portions of the dielectric material. The remaining dielectric material forms the dielectric regions 227. In some embodiment, a top surface of the dielectric region 227 can be level with a top surface of the gate electrode 220. In some embodiments, the deposition of the dielectric material of the dielectric regions 227 is performed using a conformal deposition process such as ALD, which may be PEALD, thermal ALD, or the like. In some embodiments, material of the dielectric regions 227 is substantially the same as that shown in FIGS. 2A and 2B, and the related detailed descriptions may refer to the foregoing paragraphs, and are not described again herein for the purpose of simplicity and clarity.

An etch back process is performed on the gate electrodes 220 and the gate spacer 233 to form the hard mask layer 235. Specifically, the etch back process may include a bias plasma etching step. The bias plasma etching step may be performed to remove portions of the gate electrode 220 and the gate spacer 233. Portions of the gate trenches may reappear with shallower depth. Top surfaces of the gate electrode 220 and the gate spacer 233 may be not level with the ILD layer 260. In some embodiments, the bias plasma etching step may use a gas mixture of Cl₂, O₂, BCl₃, and Ar with a bias in a range from about 25V to about 1200V.

As illustrated in FIG. 18B, dielectric-based gates 225 can be formed to replace with some gate structures formed of the gate dielectric layer 231 and the gate electrodes 220. In SRAM designs, it's common to implement channel layer cuts (or in the oxide definition (OD)) at the drain-node ends of pull-up transistors to isolate adjacent cells. This segmented channel layer 210, contrasting with the continuous channel layer 210 under the pass-gate and pull-down transistors, can lead to layout-induced effects (LOD) and mismatch issues between pass-gate and pull-down transistors. This happens because the pull-down transistor operates in a denser layout environment, whereas the pass-gate transistor encounters discontinuities in the channel layer 210. Therefore, a continuous channel layer 210 alongside the dielectric-based gate 225 can mitigate issues, such as channel layer end shrinkage control for pull-down transistors and improve layout effects. In some embodiments, the dielectric-based gate 225 can form an isolation region separating the source/drain regions of neighboring semiconductor devices from each other, and thus the different semiconductor devices can be separated.

The dielectric-based gate 225, placed between the gate spacer 233, can interrupt the channel layer 210 at a depth surpassing the bottom of adjacent source/drain regions 218. The dielectric-based gate 225 may include dielectric-based gates 225a and 225b. In some embodiments, the dielectric-based gate 225 can downwardly extend deeper than the top surfaces of the fin strips 101 a vertical dimension D3. By way of example and not limitation, the vertical dimension D3 can be in a range from about 15 to 150 nm, such as about 15, 20, 30, 40, 50, 60, 70, 80, 90, 100, 110, 120, 130, 140, or 150 nm. In some embodiments, the dielectric-based gate 225 can include a single layer or multiple layers of different dielectric materials. In some embodiments, the dielectric-based gate 225 can be interchangeably referred to a dielectric pattern, a dielectric strip, or a dielectric layer. The material of the dielectric-based gate 225 is different from the material of the gate structures 220. In some embodiments, the dielectric-based gate 225 can be made of silicon oxide (SiOₓ), silicon nitride (SiₓN_{y}), silicon oxynitride (SiON), dielectric material(s), other suitable material, or a combination thereof.

In some embodiments, the hard mask layer 235 is formed over the gate electrode 220, the dielectric-based gates 225 and the gate spacer 233 using, for example, a deposition process to deposit a dielectric material over the substrate 105, followed by a CMP process to remove excess dielectric material above the ILD layer 260. The hard mask layer 235 has different etch selectivity than the ILD layer 260, so as to selective etch back the hard mask layer 235 rather than the ILD layer 260. By way of example, if the hard mask layer 235 is made of silicon nitride, the ILD layer 260 may be made of a dielectric material different from silicon nitride. If the hard mask layer 235 is made of silicon carbide (SiC), the ILD layer 260 may be made of a dielectric material different from silicon carbide. Therefore, the hard mask layer 235 can be used to define self-aligned gate contact region and thus referred to as a self-aligned contact (SAC) structure or a SAC layer. In some embodiments, the hard mask layer 235 may have a thickness in a range from about 2 nm to about 60 nm, such as about 2, 5, 10, 15, 20, 25, 30, 35, 40, 45, 50, 55, or 60 nm. In some embodiments, material of the hard mask layer 235 is substantially the same as that shown in FIGS. 5A-5C, and the related detailed descriptions may refer to the foregoing paragraphs, and are not described again herein for the purpose of simplicity and clarity.

Source/drain contacts 240 formed subsequently are formed in the ILD layer 260 by a self-aligned contact process using the hard mask layer 235 as a contact etch protection layer. The source/drain contacts 240 may include 240a, 240b, 240c, 240d, 240e and 240f. In some embodiments, as illustrated in FIGS. 18A and 18B, source/drain silicide regions 270 including the source/drain silicide regions 270a and 270b may be formed on a top of the source/drain regions 218 including the source/drain regions 218a and 218b. In some embodiments, a bottom of the source/drain regions 218 can be in contact with the well region.

Subsequently, an ILD layer 262 may be deposited over the hard mask layers 235, the source/drain contacts 240, the gate end dielectric structures 237, and the dielectric gates 230. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. In some embodiments, as illustrated in FIGS. 18A and 18B, the source/drain contacts 240 are formed so that most of the ILD layers 260 between the gate spacers 233 are removed. The remaining portions of the ILD layers 260 may be collected as underlying portions of the ILD layer 262 and extends between the source/drain regions 218, as illustrated in FIGS. 3C through 3F.

Subsequently, an interconnect structure including metal lines and vias can be formed over the ILD layer 262 to electrically connect to the corresponding gate vias 250 or the corresponding source/drain contact vias 244. The metal lines can contain the metal lines M1 including the metal lines M1-Vdd, M1-Vss, M1-LI1, M1-LI2, M1-BL, M1-BLB and M1-WL, the metal lines M2 including the metal lines M2-WLO, M2-WLE and M2-INT, and the metal lines M3 including the metal lines M3-Vss, M3-BL and M3-BLB. The metal vias can include the interconnect vias via-1 (V1) and via-2 (V2). In some embodiments, materials of the metal lines and vias may be made of a conductive material, such as Cu, Co, Ru, Pt, Al, W, Ti, TaN, TiN, or any combinations thereof. Also included in the interconnect structure is an inter-metal dielectric (IMD) layer 264. The IMD layer 264 may provide electrical insulation as well as structural support for the various features of the interconnect structure. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the IMD layer 264 may be made of an oxide, nitride, the like, or combinations thereof.

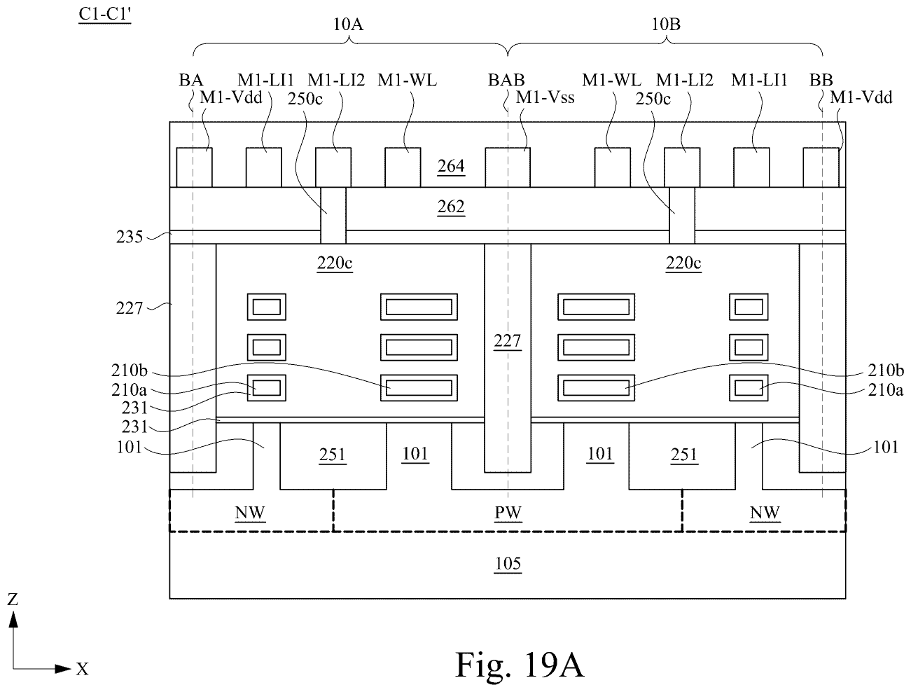

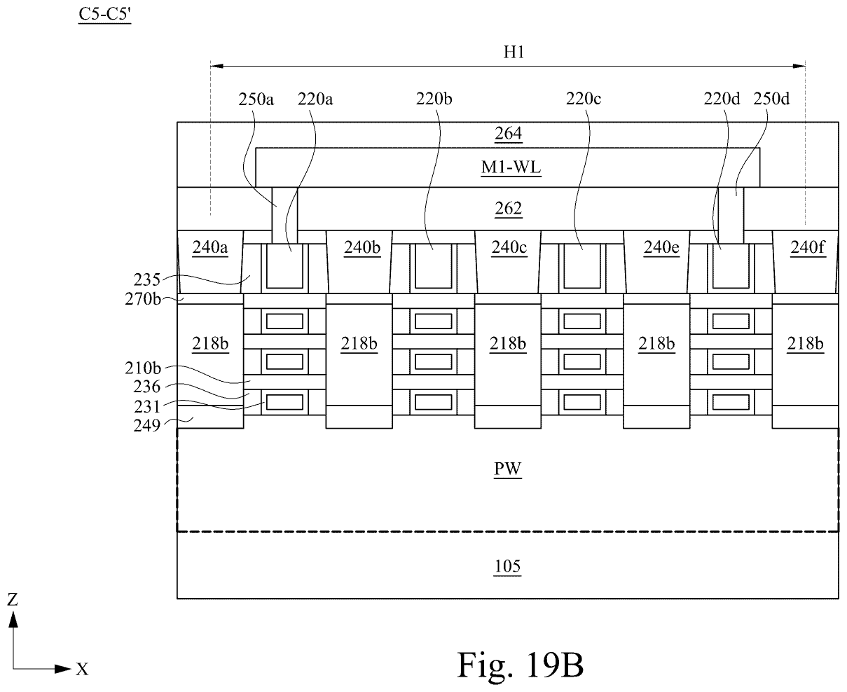

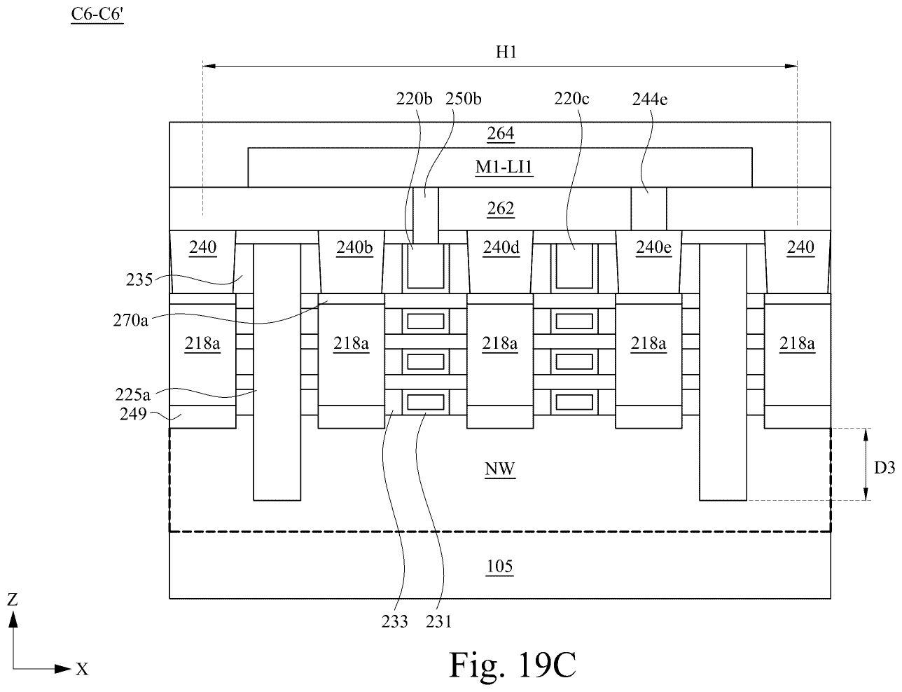

As an example to form the conductive lines in the interconnect structure, trenches/openings for the conductive lines are formed through the IMD layer. The trenches/openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the IMD layer. The remaining liner and conductive material form the conductive lines in the trenches/openings. The conductive lines may be formed in distinct processes, or may be formed in the same process. In some embodiments, material and manufacturing method of the conductive lines (not shown) in other metallization layers are substantially the same as those of the conductive line in the first metallization layer as shown in FIGS. 19A-19C, and the related detailed descriptions may refer to the foregoing paragraphs, and are not described again herein for the purpose of simplicity and clarity and does not in itself dictate a relationship between the various embodiments and/or configurations discussed.

According to one or more embodiments of the present disclosure, a method of forming a semiconductor structure includes a number of operations. A first static random access memory (SRAM) cell is formed over a semiconductive substrate. A second SRAM cell is formed over the semiconductive substrate and adjacent to the first SRAM cell. A first source/drain contact is formed across the first and second SRAM cells, wherein the first source/drain contact is electrically coupled to a source/drain region of a first pass-gate transistor in the first SRAM cell and a source/drain region of a second pass-gate transistor in the second SRAM cell. A first source/drain contact via is formed over the first source/drain contact. In one or more embodiments of the present disclosure, the first source/drain contact via extends along a longitudinal direction of a gate electrode of the first pass-gate transistor. In some embodiments, from a top view the first source/drain has a length-to-width ratio in a range from about 2 to about 5. In one or more embodiments of the present disclosure, the method further includes a number of operations. A second source/drain contact is formed across the first and second SRAM cells, wherein the second source/drain contact is electrically coupled to a source/drain region of a third pass-gate transistor in the first SRAM cell and a source/drain region of a fourth pass-gate transistor in the second SRAM cell. A second source/drain contact via is formed over the second source/drain contact, wherein the second source/drain contact via extends along a longitudinal direction of a gate electrode of the third pass-gate transistor. In some embodiments, the first and third pass-gate transistors share the same active region in the first SRAM cell. In one or more embodiments of the present disclosure, forming the first SRAM cell includes forming a semiconductor sheet over the semiconductive substrate and forming a gate electrode overlapping the semiconductor sheet. In one or more embodiments of the present disclosure, forming the first SRAM cell includes forming a dielectric-based gate on a boundary of the first SRAM cell. In some embodiments, a longitudinal end of the dielectric-based gate abuts a longitudinal end of a gate electrode of the first pass-gate transistor. In one or more embodiments of the present disclosure, forming the first SRAM includes forming an isolation transistor on a boundary of the first SRAM cell. In one or more embodiments of the present disclosure, the first and second SRAM cells are arranged along a longitudinal direction of a gate electrode of the first pass-gate transistor. In some embodiments, the first and second SRAM cells are arranged along a longitudinal direction of a gate electrode of the first pass-gate transistor.

According to one or more embodiments of the present disclosure, a method of forming a semiconductor structure includes a number of operations. Adjacent first and second static random access memory (SRAM) cells are formed over a substrate, wherein the first and second SRAM cells are arranged in a first direction. A first metal line is formed and electrically coupled to a source/drain region of a first pass-gate transistor in the first SRAM cell and a source/drain region of a second pass-gate transistor in the second SRAM cell. A second metal line is formed over the first metal line and electrically coupled to the first metal line through a first interconnect via. Aa third metal line is formed over the second metal line and electrically coupled to the second metal line through a second interconnect via, wherein the third metal line includes a first conductive pattern extends in a second direction different from the first direction and a second conductive pattern extends from a side of the first conductive pattern in the first direction, and both of the first and second conductive patterns of the third metal line partially overlap the second interconnect via. In one or more embodiments of the present disclosure, the first and second interconnect vias are offset from each other in the first direction. In one or more embodiments of the present disclosure, an area of the second interconnect via overlapped by the first and second conductive pattern is greater than 75% of a total area of the second interconnect via. In one or more embodiments of the present disclosure, the first and second conductive patterns of the third metal line are included in a bit line metal line. In one or more embodiments of the present disclosure, the second metal line includes a word line metal line extending in the second direction and across the first and second SRAM cells. In one or more embodiments of the present disclosure, forming the first and second SRAM further includes forming a plurality of semiconductor sheets over the substrate and forming a gate structures wrapping around the semiconductor sheets.

According to one or more embodiments of the present disclosure, a semiconductor structure includes a substrate, a first static random access memory (SRAM) cell, a second SRAM cell and a first source/drain contact. The first SRAM cell is over the substrate and includes a first pull-down transistor and a second pull-down transistor sharing a first common source/drain region. The second SRAM cell abuts the first SRAM cell and includes a third pull-down transistor and a fourth pull-down transistor sharing a second common source/drain region. The first source/drain contact is over the first common source/drain region shared by the first and second pull-down transistors, and the second common source/drain region shared by the third and fourth pull-down transistors. In one or more embodiments of the present disclosure, the first SRAM cell includes a first pass-gate transistor. The second SRAM cell includes a second pass-gate transistor. The semiconductor structure further includes a second source/drain contact over a source/drain region of the first pass-gate transistor in the first SRAM cell and a source/drain region of the second pass-gate transistor in the second SRAM cell. In some embodiments, the first SRAM cell includes a third pass-gate transistor. The second SRAM cell includes a fourth pass-gate transistor. The semiconductor structure further includes a third source/drain contact over a source/drain region of the third pass-gate transistor in the first SRAM cell and a source/drain region of the fourth pass-gate transistor in the second SRAM cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first static random access memory (SRAM) cell over a semiconductive substrate;
forming a second SRAM cell over the semiconductive substrate and adjacent to the first SRAM cell;
forming a first source/drain contact across the first and second SRAM cells, wherein the first source/drain contact is electrically coupled to a source/drain region of a first pass-gate transistor in the first SRAM cell and a source/drain region of a second pass-gate transistor in the second SRAM cell; and
forming a first source/drain contact via over the first source/drain contact.

2. The method of claim 1, wherein the first source/drain contact via extends along a longitudinal direction of a gate electrode of the first pass-gate transistor.

3. The method of claim 2, wherein from a top view the first source/drain has a length-to-width ratio in a range from about 2 to about 5.

4. The method of claim 1, further comprising:
forming a second source/drain contact across the first and second SRAM cells, wherein the second source/drain contact is electrically coupled to a source/drain region of a third pass-gate transistor in the first SRAM cell and a source/drain region of a fourth pass-gate transistor in the second SRAM cell; and
forming a second source/drain contact via over the second source/drain contact, wherein the second source/drain contact via extends along a longitudinal direction of a gate electrode of the third pass-gate transistor.

5. The method of claim 4, wherein the first and third pass-gate transistors share the same active region in the first SRAM cell.

6. The method of claim 1, wherein forming the first SRAM cell comprises:
forming a semiconductor sheet over the semiconductive substrate; and
forming a gate electrode overlapping the semiconductor sheet.

7. The method of claim 1, wherein forming the first SRAM cell comprises:
forming a dielectric-based gate on a boundary of the first SRAM cell.

8. The method of claim 7, wherein a longitudinal end of the dielectric-based gate abuts a longitudinal end of a gate electrode of the first pass-gate transistor.

9. The method of claim 1, wherein forming the first SRAM comprises:
forming an isolation transistor on a boundary of the first SRAM cell.

10. The method of claim 1, wherein the first and second SRAM cells are arranged along a longitudinal direction of a gate electrode of the first pass-gate transistor.

11. The method of claim 10, further comprising:
forming a word line over the first and second SRAM cell, the word line extends along the longitudinal direction of the gate electrode of the first pass-gate transistor.

12. A method, comprising:
forming adjacent first and second static random access memory (SRAM) cells over a substrate, wherein the first and second SRAM cells are arranged in a first direction;
forming a first metal line electrically coupled to a source/drain region of a first pass-gate transistor in the first SRAM cell and a source/drain region of a second pass-gate transistor in the second SRAM cell;
forming a second metal line over the first metal line and electrically coupled to the first metal line through a first interconnect via; and
forming a third metal line over the second metal line and electrically coupled to the second metal line through a second interconnect via, wherein the third metal line comprises a first conductive pattern extends in a second direction different from the first direction and a second conductive pattern extends from a side of the first conductive pattern in the first direction, and both of the first and second conductive patterns of the third metal line partially overlap the second interconnect via.

13. The method of claim 12, wherein the first and second interconnect vias are offset from each other in the first direction.

14. The method of claim 12, wherein an area of the second interconnect via overlapped by the first and second conductive pattern is greater than 75% of a total area of the second interconnect via.

15. The method of claim 12, wherein the first and second conductive patterns of the third metal line are comprised in a bit line metal line.

16. The method of claim 12, wherein the second metal line comprises a word line metal line extending in the second direction and across the first and second SRAM cells.

17. The method of claim 12, wherein forming the first and second SRAM further comprises:
forming a plurality of semiconductor sheets over the substrate; and
forming a gate structures wrapping around the semiconductor sheets.

18. A semiconductor structure, comprising:
a substrate;
a first static random access memory (SRAM) cell over the substrate and comprising a first pull-down transistor and a second pull-down transistor sharing a first common source/drain region;
a second SRAM cell abutting the first SRAM cell and comprising a third pull-down transistor and a fourth pull-down transistor sharing a second common source/drain region; and
a first source/drain contact over the first common source/drain region shared by the first and second pull-down transistors, and the second common source/drain region shared by the third and fourth pull-down transistors.

19. The semiconductor structure of claim 18, wherein the first SRAM cell further comprises a first pass-gate transistor, the second SRAM cell comprises a second pass-gate transistor, and the semiconductor structure further comprises:
a second source/drain contact over a source/drain region of the first pass-gate transistor in the first SRAM cell and a source/drain region of the second pass-gate transistor in the second SRAM cell.

20. The semiconductor structure of claim 19, wherein the first SRAM cell further comprises a third pass-gate transistor, the second SRAM cell further comprises a fourth pass-gate transistor, and the semiconductor structure further comprises:
a third source/drain contact over a source/drain region of the third pass-gate transistor in the first SRAM cell and a source/drain region of the fourth pass-gate transistor in the second SRAM cell.
